(19) United States
(12) Patent Application Publication
(10) Pub. No.: US 2025/0155732 A1
(43) Pub. Date: May 15, 2025

(54) THERMAL ARCHITECTURE DESIGNS FOR A HEAD-WORN DEVICE, AND SYSTEMS AND METHODS OF USE THEREOF

(71) Applicant: Meta Platforms Technologies, LLC, Menlo Park, CA (US)

(72) Inventors: Alex Ockfen, Bothell, WA (US); Hunter Cantrell, Vancouver, WA (US)

(21) Appl. No.: 18/936,860

(22) Filed: Nov. 4, 2024

Related U.S. Application Data
(60) Provisional application No. 63/598,641, filed on Nov. 14, 2023.

(51) Int. Cl. G02C 11/00; G02C 5/14; H05K 7/20

(52) U.S. Cl. CPC G02C 11/10; G02C 5/14; H05K 7/20336

(57) ABSTRACT

A head-worn device that includes a lens frame, a first temple arm, one or more electrical components, and a heat-transfer component. The lens frame is configured to hold at least two lenses in place. The first temple arm is coupled to the lens frame via a hinge. The one or more electrical components are located within the lens frame, and the one or more electrical components emit heat when operating. The heat-transfer component is configured to transfer the heat from the one or more electrical components to the first temple arm, and the transferring the heat from the one or more electrical components to the first temple arm is configured to cause a lengthening of a time duration during which the one or more electrical components can operate at their respective thermal design power (TDP).

### RELATED APPLICATION

This application claims priority to U.S. Provisional Application Ser. No. 63/598,641, filed Nov. 14, 2023, entitled “Thermal Architecture Designs for A Head-Worn Device, And Systems and Methods of Use Thereof,” which is hereby incorporated herein by reference in its entirety.

### TECHNICAL FIELD

The present disclosure relates generally to distribution and dissipation of heat at a head-worn device (e.g., augmented-reality glasses), including transferring heat from locations on the head-worn device configured to be in contact with a wearer's skin to other locations on the head-worn device configured to not be in contact with a wearer's skin, thereby making the head-worn device more comfortable for the wearer.

### BACKGROUND

Typical head-worn artificial reality devices require large amounts of central processing power and graphics processing power to provide an immersive user experience. The computational demands of artificial reality devices, however, produce significant amounts of byproduct heat. This byproduct heat is not only potentially harmful to electronic components, but it also makes the head-worn artificial reality device uncomfortable for the user to wear, as the byproduct heat is emitted around and into the user's face. Traditional passive cooling systems can concentrate heat in specific locations creating uncomfortable hot spots for the wearer, which can prompt the wearer to take the head-worn artificial reality device off. Traditional active cooling systems, such as fans, are impractical for head-worn artificial reality devices due to both their size and the noise they produce, which can interfere with the user's immersion. Due to these problems, the immersive quality of artificial reality experiences is limited not by processor or graphic capabilities, but rather the ability of the artificial reality device to dissipate byproduct heat from its electronic components.

As such, there is a need for a head-worn artificial reality device that is capable of dissipating byproduct heat that is both efficient and comfortable for the user. A brief summary of solutions to the issues noted above are described below.

### SUMMARY

One example of thermal architecture of a head-worn device (e.g., an artificial reality headset configured to display an artificial-reality) is described herein. This example head-worn device includes a lens frame, a first temple arm, one or more electrical components, and a heat-transfer component. The one or more programs including instructions for performing operations. The lens frame is configured to hold at least two lenses (e.g., a first and waveguide). The first temple arm is coupled to the lens frame via a hinge (e.g., a hinge configured to rotate within a socket). The one or more electrical components are located within the lens frame, and the one or more electrical components emit byproduct heat when operating. The heat-transfer component is configured to transfer the byproduct heat from the one or more electrical components to the first temple arm. The transferring of the byproduct heat from the one or more electrical components to the first temple arm is configured to cause a lengthening of a time duration (e.g., run at an extended period of 5-30 minutes instead of 5 seconds based on environmental conditions) during which the one or more electrical components can operate at their respective thermal design power (TDP) (e.g., a maximum amount of heat generated by electrical components that a cooling system is designed to dissipate).

Having summarized the first aspect generally related to thermal architecture of a head-worn device above, the second aspect generally related to thermal architecture of a head-worn device based on a state of the temple arms of the head-worn device is now summarized.

In another example of thermal architecture of a head-worn device (e.g., an artificial reality headset configured to display an artificial-reality), the head-worn device includes a lens frame coupled to a hinged temple arm (e.g., a temple arm coupled to the lens frame via a hinge), and the hinged temple arm has an open state (e.g., the hinged temple arm is substantially perpendicular to the lens frame) and a state other than open (e.g., the hinged temple arm is substantially parallel to the lens frame). The lens frame includes one or more waste heat emitting components and the hinged temple arm when the hinged temple arm is in the open state. The head-worn device is configured to have a first waste heat transfer rate between the one or more waste heat emitting components and the hinged temple arm when the hinged temple arm is in the open state. The head-worn device is configured to have a second waste heat transfer rate between the one or more waste heat emitting components and the hinged temple arm when the hinged temple arm is in the state other than the open state. The first heat transfer rate is greater than the second heat transfer rate.

The features and advantages described in the specification are not necessarily all inclusive and, in particular, certain additional features and advantages will be apparent to one of ordinary skill in the art in view of the drawings, specification, and claims. Moreover, it should be noted that the language used in the specification has been principally selected for readability and instructional purposes.

Having summarized the above example aspects, a brief description of the drawings will now be presented.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the figures.

FIG. 1 illustrates an example head-worn device capable of transferring heat between components of the head-worn device, in accordance with some embodiments.

FIG. 2A illustrates an example head-worn device that transfers heat between its lens frame and temple arms via heat pad located at the hinges of the head-worn device, in accordance with some embodiments.

FIG. 2B illustrates an example head-worn device that transfers heat between its lens frame and temple arms via a heat-transfer component located at the hinges of the head-worn device, in accordance with some embodiments.

FIG. 3 illustrates example continuous skin-contact regions of a head-worn device, in accordance with some embodiments.

FIG. 4 illustrates an example head-worn device that transfers heat between its lens frame and lenses via a heat-transfer component located in the lens frame of the head-worn device, in accordance with some embodiments.

FIGS. 5A-5B illustrate an example head-worn device that changes its thermal design power (TDP) based on variations in an external thermal environment, in accordance with some embodiments.

FIGS. 6A-6C-2 illustrate example artificial-reality systems, in accordance with some embodiments.

FIGS. 7A-7B illustrate an example wrist-wearable device, in accordance with some embodiments.

FIGS. 8A-8C illustrate example head-wearable devices, in accordance with some embodiments.

FIGS. 9A-9B illustrate an example handheld intermediary processing device, in accordance with some embodiments.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method, or device. Finally, like reference numerals may be used to denote like features throughout the specification and figures.

### DETAILED DESCRIPTION

Numerous details are described herein to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not necessarily been described in exhaustive detail so as to avoid obscuring pertinent aspects of the embodiments described herein.

Embodiments of this disclosure can include or be implemented in conjunction with various types or embodiments of artificial-reality systems. Artificial-reality (AR), as described herein, is any superimposed functionality and or sensory-detectable presentation provided by an artificial-reality system within a user's physical surroundings. Such artificial-realities can include and/or represent virtual reality (VR), augmented reality, mixed artificial-reality (MAR), or some combination and/or variation one of these. For example, a user can perform a swiping in-air hand gesture to cause a song to be skipped by a song-providing API providing playback at, for example, a home speaker. An AR environment, as described herein, includes, but is not limited to, VR environments (including non-immersive, semi-immersive, and fully immersive VR environments); augmented-reality environments (including marker-based augmented-reality environments, markerless augmented-reality environments, location-based augmented-reality environments, and projection-based augmented-reality environments); hybrid reality; and other types of mixed-reality environments.

Artificial-reality content can include completely generated content or generated content combined with captured (e.g., real-world) content. The artificial-reality content can include video, audio, haptic events, or some combination thereof, any of which can be presented in a single channel or in multiple channels (such as stereo video that produces a three-dimensional effect to a viewer). Additionally, in some embodiments, artificial reality can also be associated with applications, products, accessories, services, or some combination thereof, which are used, for example, to create content in an artificial reality and/or are otherwise used in (e.g., to perform activities in) an artificial reality.

A hand gesture, as described herein, can include an in-air gesture, a surface-contact gesture, and or other gestures that can be detected and determined based on movements of a single hand (e.g., a one-handed gesture performed with a user's hand that is detected by one or more sensors of a wearable device (e.g., electromyography (EMG) and/or inertial measurement units (IMU)s of a wrist-wearable device) and/or detected via image data captured by an imaging device of a wearable device (e.g., a camera of a head-wearable device)) or a combination of the user's hands. In-air means, in some embodiments, that the user hand does not contact a surface, object, or portion of an electronic device (e.g., a head-wearable device or other communicatively coupled device, such as the wrist-wearable device), in other words the gesture is performed in open air in 3D space and without contacting a surface, an object, or an electronic device. Surface-contact gestures (contacts at a surface, object, body part of the user, or electronic device) more generally are also contemplated in which a contact (or an intention to contact) is detected at a surface (e.g., a single or double finger tap on a table, on a user's hand or another finger, on the user's leg, a couch, a steering wheel, etc.). The different hand gestures disclosed herein can be detected using image data and/or sensor data (e.g., neuromuscular signals sensed by one or more biopotential sensors (e.g., EMG sensors) or other types of data from other sensors, such as proximity sensors, time-of-flight sensors, sensors of an inertial measurement unit, etc.) detected by a wearable device worn by the user and/or other electronic devices in the user's possession (e.g., smartphones, laptops, imaging devices, intermediary devices, and/or other devices described herein).

The methods and devices described herein include thermal architectures for transferring heat between components of a head-wearable device. As described herein, thermal design power (TDP) is a maximum amount of heat generated by electrical components that a cooling system is designed to dissipate.

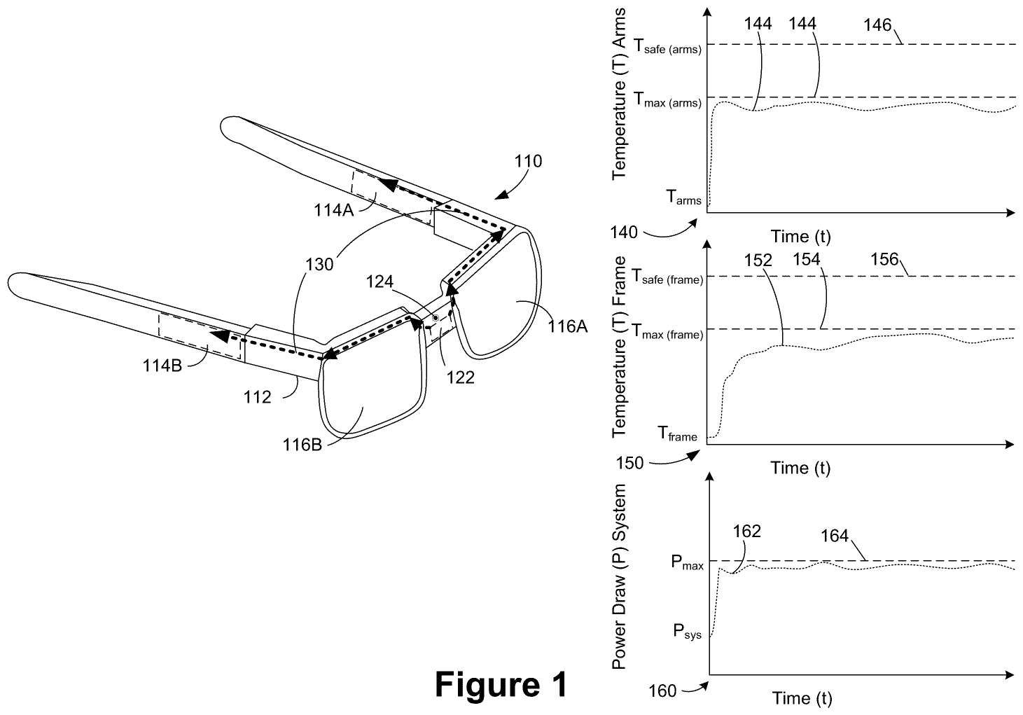

FIG. 1 illustrates an example of a head-worn device 110 capable of transferring heat between components of the head-worn device 110, in accordance with some embodiments. In some embodiments, the head-worn device 110 is an artificial reality headset configured to present an artificial reality. While the examples provided below discuss transferring heat from one set of electronic components to one or both temple arms, the following heat-transfer techniques can be applied to individual temple arms or both temple arms. A non-extensive list of example heat-transfer modalities can include, (i) one set electronics in the frame transferring heat to one temple arm (ii) two distinct (thermally uncoupled) sets of electronics in the frame each transferring heat to different temple arms, (iii) two distinct (thermally uncoupled) sets of electronics transferring heat to a single temple arm either by the same heat-transfer medium or multiple heat-transfer mediums, (iv) electronics located in one or both of the temple arms transferring heat to the frame, (v) transferring heat bidirectionally based on whether the temple arm or the frame has thermal overhead to accommodate additional heat, etc.

In some embodiments, the head-worn device 110 includes a frame 112 that is configured to hold at least two lenses 116A-116B. The frame includes electrical components 122 (e.g., an electrical component that produces byproduct heat when powered on) and at least one heat-transfer component (e.g., indicated by arrows 130) is configured to transfer the byproduct heat from the electrical components 122. The frame 112 is coupled to two temple arms 114A-114B, which can be configured to have the byproduct heat transferred to them from the electrical components 122 by the at least one heat-transfer component. In some embodiments, the frame 112 is coupled to the two temple arms 114A-114B by respective hinges (not pictured). In some embodiments, the hinges are configured to orbit within a socket to adjust the fit of the head-worn device on the user's head. In some embodiments, the electrical components 122 can include one or more processors, a display projector component, an integrated circuit, computer-readable storage, an imaging device 124 (e.g., an IR sensor, an image capture sensor, a video camera, etc.), a simultaneous localization and mapping (SLAM) camera, a radio component, a graphics processor, a sensor, and/or inertial measurement sensors. In some embodiments, the at least two lenses each include a respective waveguide for receiving a projected artificial reality.

In some embodiments, the at least one heat-transfer component is configured to transfer the heat (e.g., the byproduct heat) from the at least one electrical component 122 to at least one of the two temple arms 114A-114B. The transferring of the heat from the at least one electrical component 122 to at least one of the two temple arms 114A-114B lengthens a time duration at which the at least one electrical component 122 can operate at optimal performance (e.g. the at least one electrical component 122 runs at an extended period of 5-30 minutes instead of 5 second based on environmental conditions). The at least one electrical component 122 operates at an optimal performance when it does not need to decrease a respective clock rate of its respective processors to continue operating at its TDP. In some embodiments, the heat can be actively routed to one of the two temple arms 114A-114B based on respective thermal capacities of the two temple arms. In some embodiments, the respective thermal capacities of the two temple arms are respective maximum temperatures.

As shown in chart 140, line 142 (labelled Tarms) indicates that a temperature of the two temple arms 114A-114B remains below a maximum-temple-arm temperature, as indicated by line 144 (labelled Tmax (arms)). The maximum-temple-arm temperature is below a safe-temple-arm-temperature, as indicated by line 146 (labelled Tsafe (arms)), which is not harmful or uncomfortable (e.g., a temperature below being harmful but my induce irritation, such as sweating) to the user while wearing the head-worn device 110. As shown in chart 150, line 152 (labelled Tframe) indicates that a temperature of the frame 112 remains below a maximum-frame temperature, as indicated by line 152 (labelled Tmax (frame)). The maximum-frame temperature is below a safe-frame temperature, as indicated by line 154 (labelled Tsafe (arms)), which is not harmful or uncomfortable (e.g., a temperature below being harmful but my induce irritation, such as sweating) to the user while wearing the head-worn device 110. As shown in chart 160, line 162 (labelled Psys), indicates that a power draw of the at least one electrical component 122 remains below a maximum-electronics power draw, as indicated by line 164 (labelled Pmax). In some embodiments, the maximum-electronics power draw is a TDP of the at least one electronics component 122.

In some embodiments, the two temple arms 114A-114B include at least one second electrical component. The at least one second electrical component produces additional heat (e.g., byproduct heat from the at least one second electrical component) when in use. In some embodiments, the head-worn device 110 further includes at least one second heat-transfer component that is configured to transfer the additional heat from the at least one second electrical component to the frame 112. The transferring of the additional heat from the at least one second electrical component to the second location lengthens a time duration the at least one third electrical component can operate at optimal performance.

In some embodiments, the frame 112 is constructed of at least one of magnesium, a magnesium alloy, a polycarbonate, a plastic composite material (e.g., a fiber-reinforced plastic), an aluminum metal matrix composite, a magnesium metal matrix composite, and a titanium metal matrix composite. In some embodiments, the at least one temple arm 114 is constructed of at least one of magnesium, a magnesium alloy, a polycarbonate, a plastic composite material (e.g., a fiber-reinforced plastic), an aluminum metal matrix composite, a magnesium metal matrix composite, and a titanium metal matrix composite. In some embodiments, the frame 112 and the at least one temple arm are constructed of different materials.

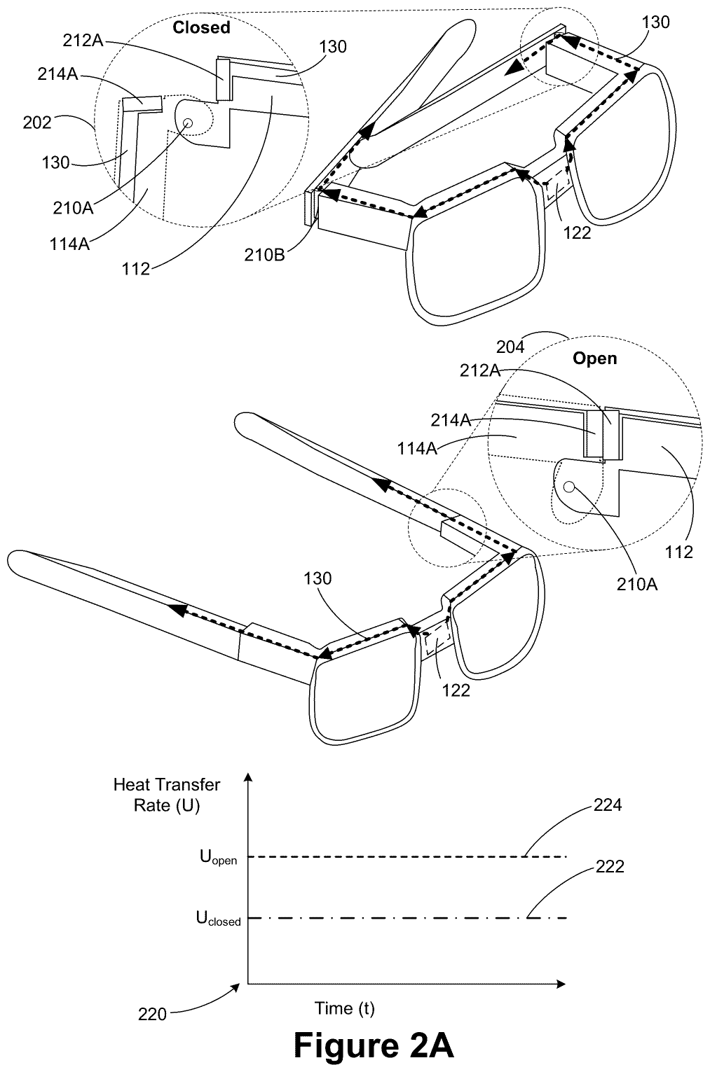

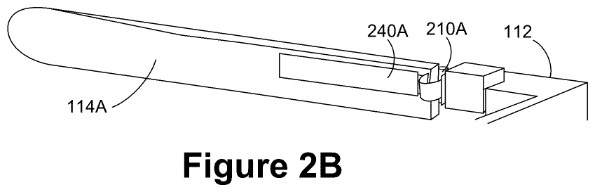

FIGS. 2A-2B illustrate components for transferring heat from the electrical components 122 to one or both of the two temple arms 114A-114B, in accordance with some embodiments. The heat transfer component of the frame 112 transfers the heat from the electrical components 122 to the two temple arms 114A-114B via heat-transfer pathways. The two temple arms include at least one heat-emitting component (e.g., one or more electrical components that produce byproduct heat when in use), and byproduct heat from those components can be transferred to the frame using the same heat-transfer pathways described in reference to FIG. 2A. In some embodiments, the heat-transfer pathways can be configured to transfer heat to locations that provide the best combination of heat-transfer via conductive cooling, radiative cooling, and inductive cooling. In some embodiments, the locations that provide the best combination of heat-transfer are locations on a surface of the frame 112 and/or the two temple arms 114A-114B that do not contact a user's skin while the user wears the head-wearable device 110. In some embodiments, inductive cooling may be possible by transferring heat to a user, so long as a predetermined maximum skin threshold temperature is not exceeded.

FIG. 2A illustrates heat-transfer pathways that work in conjunction with hinges 210A-210B for transferring heat from the at least one electronic component to at least one of the two temple arms 114A-114B, in accordance with some embodiments. Transferring heat via conduction between parts that move relative to each other requires techniques to ensure maximum heat-transfer occurs when the headset is being worn by a user (i.e., the temple arms are in an “open” state 204). FIG. 2A illustrates frame 112 connected to the two temple arms 114A and 114B by hinges 210A and 210B, respectively. The hinges 210A-210B allow the temple arms 114A-114B to move relative to the frame 112. For explanation purposes, a “closed position” 202 will refer to the temple arms 114A-114B being in a position such that the temple arms are substantially parallel to the frame 112, and an “open position” 204 will refer to the temple arms 114A and 114B being substantially perpendicular to the frame 112 (e.g., FIG. 2A shows a closed position 202 and an open position 204).

A first technique for transferring heat includes using thermally conductive pads to facilitate heat-transfer when the headset is in an open state. The frame 112 includes a first-frame heat-transfer pad 212A and a second-frame heat-transfer pad 212B, and the two temple arms 114A and 114B each include a first-temple-arm-heat-transfer pad 214A and a second-temple-arm-heat-transfer pad 214B, respectively. The first-frame heat-transfer pad 212A and the second-frame heat-transfer pad 212B are configured to contact the first-temple-arm-heat-transfer pad 214A and the second-temple-arm-heat-transfer pad 214B, respectively, while the two temple arms are in the open state 204. In some embodiments, when the hinges 210A and 210B are in the open state 204, they are configured to cause the frame-heat-transfer pads and the temple-arm-heat-transfer pads to have a contact force of at least 50 pounds per square inch (PSI). In some embodiments, increasing the contact force increases the contact area between the frame-heat-transfer pads and the temple-arm-heat-transfer pads, thereby increasing the amount of heat that can be transferred between the frame-heat-transfer pads 212A-212B and temple-arm-heat-transfer pads 214A-214B. In some embodiments, the frame-heat-transfer pads 212A-212B and the temple-arm-heat-transfer pads 214A-214B are made of a material with high thermal conductivity (e.g., copper, aluminum, conductive alloy, carbon, silicon, etc.). In some embodiments, the frame-heat-transfer pads and the temple-arm-heat-transfer pads are made of a material with higher thermal conductivity than both a material that frame 112 and the temple arms 114A-114B are made of. In some embodiments, the frame 112 and the temple arms 114A and 114B are constructed of different materials.

For example, while the hinge 210A is in the open state 204, the first-frame heat-transfer pad 212A and the first-temple-arm-heat-transfer pad 214A are in contact with each other. The contact creates a first heat-transfer rate between the frame 112 and the first temple arm 114A. While the hinge 210A is in the closed state 202, the first-frame-heat-transfer pad 212A and the first-temple-arm-heat-transfer pad 214A are in not in contact with each other, and the hinge 210A creates a second heat-transfer rate between frame 112 and the first temple arm 114A.

FIG. 2A illustrates a chart 220 depicting the difference in heat-transfer rate between the frame 112 and the temple arms 114A-114B based on the position state of the hinges 210A-210B, in accordance with some embodiments. As shown in chart 220, line 222 (labelled Uclosed) indicates the first heat-transfer rate between the frame 112 and the temple arms 114A-114B when hinge 210A-210B are in the closed state 202. In addition, line 224 (Uopen) indicates the second heat-transfer rate between the frame 112 and the temple arms 114A-114B when hinges 210A-210B are in the open state 204. As shown in the chart 220, the heat-transfer rate is less when temple arm 114A is in an open state 204 than when the temple arm 114A is in the closed state 202, in accordance with some embodiments.

FIG. 2B illustrates an additional heat-transfer component 240A that allows heat to transfer between the frame 112 and at least one of the two temple arms 114A-114B. For example, the additional heat-transfer component 240A is coupled to the first temple arm 114A and at least one of the frame 112, the at least one electrical component 122, and the heat transfer component. The additional heat-transfer component 240A creates a third heat-transfer rate between the frame 112 and the first temple arm 114A. In some embodiments, the additional heat-transfer component 240A is configured to bend as the first hinge 210A rotates, such that the third heat-transfer rate is the same regardless of whether the first hinge 210A is in the closed state 202 or the open state 204. In some embodiments, the head-worn device 110 includes both thermally conductive pads and the additional heat-transfer component 240A for transferring heat between the frame 112 and the temple arm 214A. The thermally conductive pads and the additional heat-transfer component 240A may simultaneously transfer thermal energy between the frame 112 and the first temple arm 114A, and/or the thermally conductive pads may transfer heat between the frame 112 and the first temple arm 114A when in the open state, and the additional heat-transfer component 240A transfers heat between the frame 112 and the first temple arm 114A while in the closed state 202.

The heat-transfer component 240A may comprise of one or more layers of carbon tape and/or a flexible heat pipe. The one or more layers of carbon tape may be located inside of a structure of the frame 112 and a structure of the first temple arm 114A, and/or the carbon tape is overmolded to the frame 112 and the first temple arm 114A. In some embodiments, the carbon tape is at least one of a graphite tape and a carbon-fiber tape. In some embodiments, the flexible heat pipe is a flexible vapor chamber. In some embodiments, the heat-transfer component 240A is configured to be cycled 20,000-75,000 cycles, wherein one cycle is the first hinge 210A transitioning from the closed state 202, to the open state 204, and back to the closed state 202.

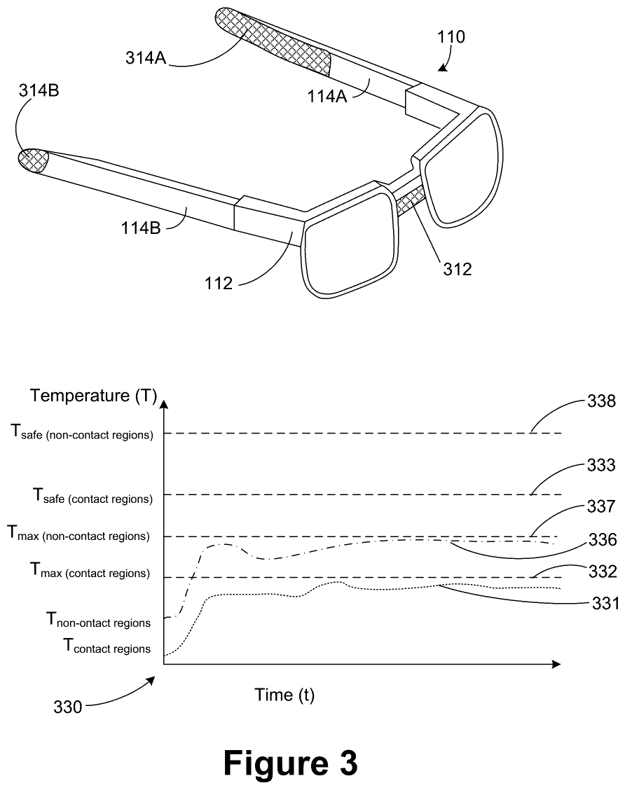

FIG. 3 illustrates continuous skin-contact regions of the head-worn device 110 while the head-worn device 110 is being worn by a wearer, in accordance with some embodiments. A first skin-contact region 312 is located on a surface of the nose bridge of the frame 112 (e.g., where the nose bridge of the head-worn device 110 contacts a wearer's nose while being worn). Two second skin-contact regions 314A-314B are located on surfaces of the two temple arms 114A-114B, respectively (e.g., where the temple arms 114A-114B contact a wearer's temples and/or cars while being worn). At least a portion of the remainder of surfaces of the frame 112 and the two temple arms 114A-114B are non-contact regions, where the non-contact regions do not regularly contact the wearer while being worn by the wearer. In some embodiments, the head-worn device 110 is configured to transfer byproduct heat to the non-contact regions (and avoid transferring byproduct heat to the continuous skin-contact regions).

As shown in chart 330, line 331 (labelled Tcontact regions) indicates that a continuous skin-contact region of the head-worn device 110 is below a maximum-contact-region temperature, as indicated by line 332 (labelled Tmax (contact regions)). The maximum-contact-region temperature is below a safe-contact-region temperature, as indicated by line 333 (labelled Tsafe (contact regions)), which ensures the head-worn device remains safe to wear. Chart 330 additionally shows that a non-contact-region temperature, as indicated by line 336 (labelled Tnon-contact regions) is below a maximum-non-contact-region temperature, as indicated by line 337 (labelled Tmax (non-contact regions)). As with the maximum-contact-region temperature, the maximum-non-contact-region temperature is below a safe-non-contact-region temperature, as indicated by line 338 (labelled Tsafe (non-contact regions)). In some embodiments, the safe-non-contact-region temperature is equal to the safe-contact-region temperature (i.e., the head-worn device has a universal safe exterior temperature). In some embodiments, the maximum-non-contact-region temperature is 10-30 degrees Celsius greater (e.g., 18 degrees greater) than the maximum-contact-region temperature. For example, the maximum-non-contact-region temperature can be 51 degrees Celsius, and the maximum-contact-region temperature may be 43 degrees Celsius.

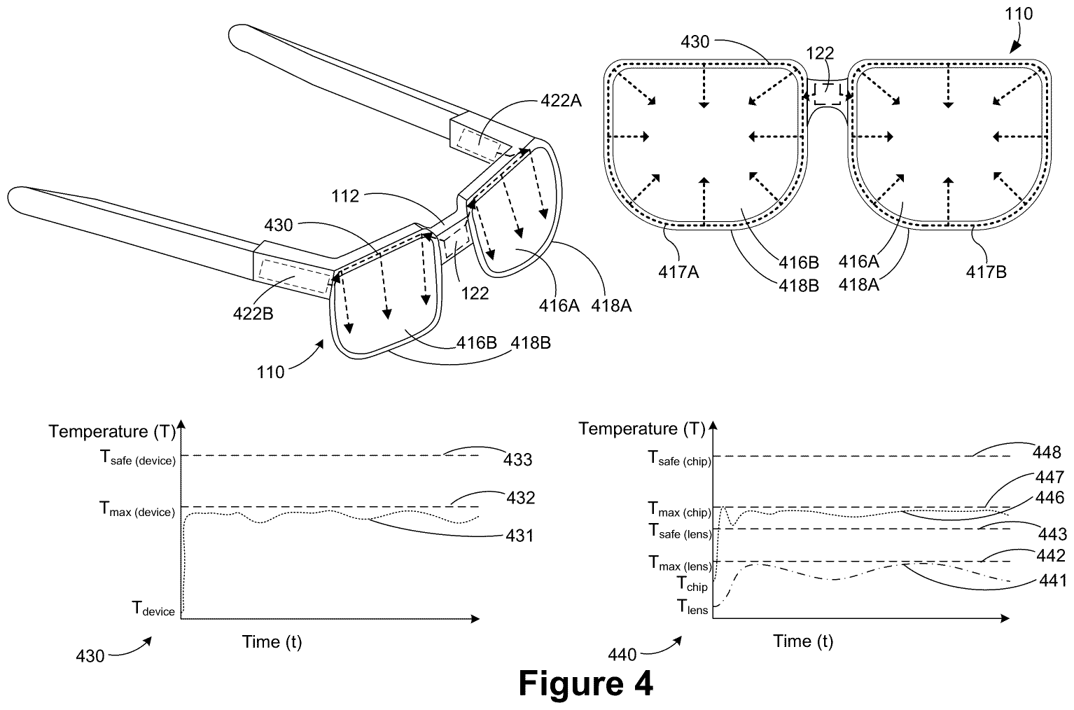

FIG. 4 illustrates thermally conductive lenses for redistributing heat from the electrical components 122 and/or the additional electronic components (e.g., a right electrical component 422A and/or a left electrical component 424B) to at least one of two thermally conductive lenses 416A-416B. FIG. 4 illustrates an exemplary embodiment of the head-worn device 110 transferring heat from the electrical components 122 and/or the additional electronic components (e.g., a right electrical component 422A and/or a left electrical component 424B) to at least one of the two conductive lenses 416A-416B via heat-transfer components (e.g., indicated by the arrows 430). Rims 418A-418B of the frame 112 surround and hold the conductive lenses 416A-416B and include heat-transfer pathways, indicated by dashed lines 417A and 417B, between the electrical components 122 and/or the additional electronic components and the conductive lenses 416A-416B. In some embodiments, the frame 112 and/or the conductive rims 418A-418B include heat pipes and/or carbon tape to transfer heat from the electrical components 122 and/or the additional electronic components to the conductive lenses 416A-416B. In some embodiments, a respective waveguide of each of the conductive lens 416A-416B spreads the transferred heat across the surface area of each of the conductive lens 416A-416B. In some embodiments, the conductive lenses 416A-416B are configured to dissipate heat by radiation cooling and/or convection cooling.

As shown in chart 430, line 431 (labelled Tdevice) indicates that a device temperature (e.g., a surface temperature of the head-worn device 110) remains below a maximum-device temperature, as indicated by line 432 (labelled Tmax (device)). The maximum-device temperature is below a safe-device temperature 433 (labelled Tsafe (device)), which ensures that the head-worn device 110 remains safe to wear. As shown in chart 440, line 441 (labelled Tlens) indicates that a lens temperature (e.g., a surface temperature of the conductive lenses 416A-416B) remains below a maximum-lens temperature, as indicated by line 442 (labelled Tmax (lens)). The maximum-lens temperature is below a safe-lens temperature, as indicated by line 443 (labelled Tsafe (lens)), which ensures that the head-worn device 110 remains safe to wear. Additionally, chart 440 shows line 446 (labelled Tchip) which indicates that a chip temperature (e.g., a temperature of the electrical components 112 and/or the additional electronic components) remains below a maximum-chip temperature, as indicated by line 447 (labelled Tmax (chip)). The maximum-chip temperature is below a safe-chip temperature, as indicated by 448 (labelled Tsafe (chip)), which corresponds to a TDP of the electrical components 112 and/or the additional electronic components.

In some embodiments, the electrical components 122 have respective TDPs and each of the electrical components 122 are able to actively adjust their respective TDPs. In some embodiments, the at least one electrical component 122 adjusts its respective TDP based on a measured temperature (e.g., a temperature measured at one or more locations on the frame 112 and/or the two temple arms 114A-114B). In some embodiments, the measured temperature corresponds to a temperature hotspot on the frame 112 and/or the two temple arms 114A-114B. The temperature hotspots are locations where the maximum non-contact-region-temperature and/or the maximum contact-region-temperature are first reached.

In some embodiments, the electrical components 122 actively adjust their respective TDPs by actively adjusting their feature set in stages based on the measured temperature. For example, one of the electrical components 122 removes a first set of features, and, if the removal of the first set of features does not cause the respective TDP to adjust sufficiently, the one of the electrical components 122 removes a second set of features.

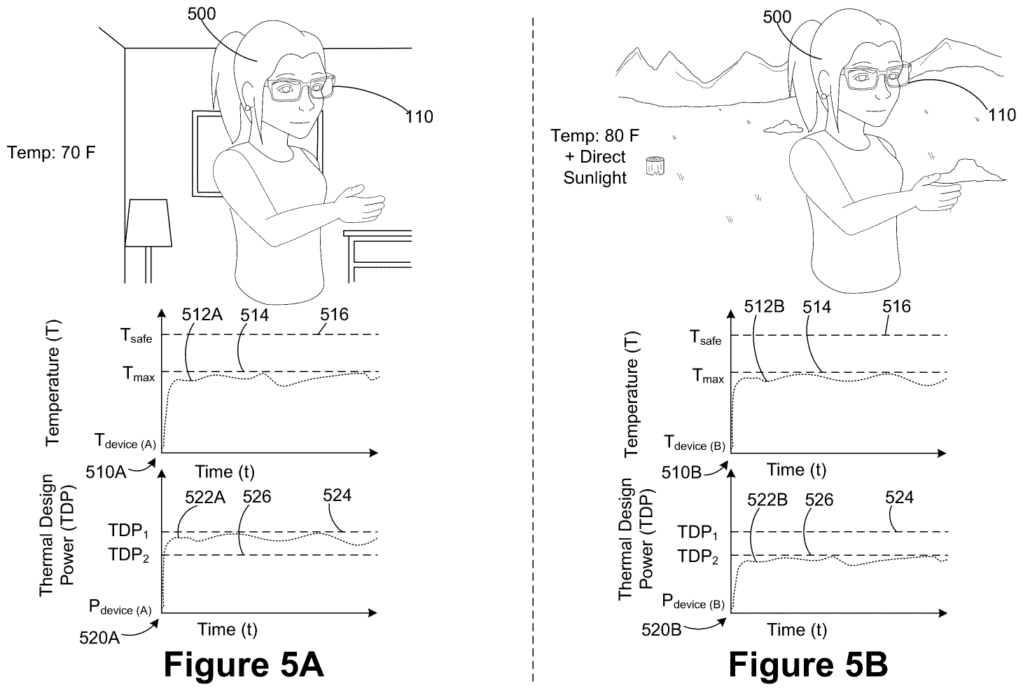

FIGS. 5A-5B illustrate an adjustment of TDP based on varying external thermal environment (e.g., the head-worn device 110 is located indoors (e.g., controlled temperature and/or out of direct sunlight) or outdoors).

FIG. 5A illustrates a first example environment (e.g., indoors) where a user 500 is wearing the head-worn device 110. As shown by temperature chart 510A, line 512 (labelled Tdevice (A)) illustrates a measurement of a temperature of the head-worn device 110 over a period of time. Chart 510A also shows that the measurement of temperature of the head-worn device 110 does not exceed a maximum-temperature threshold, as indicated by line 514 (labelled Tmax), and does not also exceed a maximum-safe temperature threshold, as indicated by line 516 (labelled Tsafe). FIG. 5A also shows a thermal design power (TDP) chart 520, which illustrates that the TDP can be adjusted based on the environment the head-worn device 110 is located. Chart 520A, which corresponds to chart 510A, shows a line 522A (labelled Pdevice (A)) that illustrates a power output of the head-worn device 110 recorded over time (i.e., the same time period as is shown in chart 510A), and does not exceed a TDP available when in the first example environment, which is indicated by a first threshold line 524 (labelled TDP1) not being crossed by the line 522A. As is shown in chart 520A, the first TDP threshold line 524 is a higher TDP threshold than the second TDP threshold line 526 (labelled TDP1). The TDP of the head-worn device 110 is variable and is at least partially dictated by the temperature of the head-worn device. In some embodiments, the TDP may adjust itself as the environment conditions change.

FIG. 5B illustrates a second example environment (e.g., outdoors) where a user 500 is wearing the head-worn device 110. As shown by temperature chart 510B, line 512B (labelled Tdevice (B)) illustrates a measurement of a temperature of the head-worn device 110 over a period of time. Chart 510B also shows that the measurement of temperature of the head-worn device 110 does not exceed a maximum-temperature threshold, as indicated by line 514 (labelled Tmax), and does not also exceed a maximum-safe temperature threshold, as indicated by line 516 (labelled Tsafe). In some embodiments, the maximum-temperature threshold and/or the maximum-safe temperature threshold is/are environment agnostic. FIG. 5B also shows a thermal design power (TDP) chart 520B, which illustrates that the TDP can be adjusted based on the environment the head-worn device 110 is located. Chart 520B, which corresponds to chart 510B, shows a line 522B (labelled Pdevice (B)) that illustrates a power output of the head-worn device 110 recorded over time (i.e., the same time period as is shown in chart 510B), and does not exceed a maximum TDP available when outdoors, which is indicated by the second threshold line 526 (labelled TDP2) not being crossed by the line 522B. As is shown in chart 520B, the second TDP threshold line 526 is lower than the first TDP threshold line 524 (labelled TDP1). The maximum TDP is variable and is at least partially dictated by the temperature of the head-worn device. In some embodiments, the TDP may adjust itself as the environment conditions change. In some embodiments, direct sun-exposure causes the head-worn device 110 to increase in temperature, which decreases the amount of heat the frame can absorb from the electronics without exceeding the thermal maximum. In some embodiments, the TDP of the at least one electrical component 122 is 2000 milliwatts when indoors.

(A1) In accordance with some embodiments, a head-worn device includes a lens frame, a first temple arm, one or more electrical components, and a heat-transfer component. The lens frame is configured to hold at least two lenses in place. The first temple arm is coupled to the lens frame via a hinge. In some embodiments, the first temple arm can further move relative the lens frame, e.g., by having a flexible temple arm that can bend between 0-20 degrees relative to the lens frame. In some embodiments, the temple arm is coupled to the lens frame without a hinge and the temple arm moves relative to the lens frame by having a flexible temple arm made at least in part by flexible material (e.g. flexure, thin material, nitinol, etc.). The one or more electrical components are located within the lens frame, and the one or more electrical components emit byproduct heat when operating. The heat-transfer component is configured to transfer the byproduct heat from the one or more electrical components to the first temple arm, and the transferring the byproduct heat from the one or more electrical components to the first temple arm is configured to cause a lengthening of a time duration during which the one or more electrical components can operate at their respective thermal design power (TDP). In some embodiments, the head-worn device is an artificial reality headset configured to display an artificial reality. In some embodiments, the at least two lenses include a first and second waveguide. In some embodiments, the hinge is configured to orbit within a socket. In some embodiments, the lengthening of the time duration allows the one or more electrical components to run for an extended period of 5-30 minutes instead of 5 seconds based on environmental conditions. In some embodiments, the thermal design power of the head-worn device is a maximum amount of heat generated by electrical components that a cooling system is designed to dissipate. For example, FIG. 1 illustrates a head-worn device 110 that includes a lens frame 112, a first temple arm 114A, one or more electrical components 122, and a heat-transfer component (indicated by arrows 130) for transferring byproduct heat from the one or more electrical components 122 to the first temple arm 114A.

(A2) In some embodiments of A1, the heat-transfer component is integrated into the hinge that couples the first temple arm to the lens frame. For example, FIG. 2B illustrates a heat-transfer component 240A integrates into a hinge 210A that couples the first temple arm 114A to the lens frame 112.

(A3) In some embodiments of any of A1-A2, the heat-transfer component is an overmolded carbon tape, such as graphite tape, that is affixed to the first temple arm and is configured to bend with the hinge.

(A4) In some embodiments of any of A1-A3, the heat-transfer component is carbon tape that is configured to bend with the hinge.

(A5) In some embodiments of any of A1-A4, the heat-transfer component is a flexible heat pipe, such as a flexible vapor chamber, that is configured to bend with the hinge.

(A6) In some embodiments of any of A1-A5, the head-worn device further includes a second temple arm is, one or more additional electrical components, and another heat-transfer component. The second temple arm is coupled to the lens frame opposite to where the first temple arm is connected to the lens frame via another hinge. The one or more additional electrical components are located within the lens frame, and the one or more additional electrical components emit additional byproduct heat when operating. The other heat-transfer component is configured to transfer the additional byproduct heat from the one or more electrical components to the second temple arm, and the transferring the additional byproduct heat from the one or more additional electrical components to the second temple arm is configured to cause a lengthening of a time duration during which the one or more additional electrical components can operate at their respective TDP. In some embodiments, the heat transferring is active, and byproduct heat can be actively routed to either the first temple arm or the second temple arm based on a thermal capacity, such as a maximum temperature, of the either the first or second temple arm. In some embodiments, active heat transferring is achieved through the use of valved vapor chambers or other methods for routing byproduct heat. In some embodiments, the lengthening of the time duration allows the one or more additional electrical components to run for an extended period of 5-30 minutes instead of 5 seconds baes on environmental conditions. For example, FIG. 1 illustrates a second temple arm 114B and another heat-transfer component (indicated by arrows 130) for transferring additional byproduct heat from one or more additional electrical components to the second temple arm 114B.

(A7) In some embodiments of any of A1-A6, the lens frame and/or the first temple arm are constructed of magnesium, or a magnesium alloy.

(A8) In some embodiments of any of A1-A7, the lens frame and/or the first temple arm are constructed of polycarbonate or a plastic composite material, such as fiber-reinforced plastic.

(A9) In some embodiments of any of A1-A8, the lens frame and/or the first temple arm are constructed of a metal matrix composite. In some embodiments, the metal matrix composite is aluminum, magnesium, and/or titanium.

(A10) In some embodiments of any of A1-A9, the one or more electrical components is a camera (such as a SLAM camera), a processor (such as a central processing unit, a secondary processing unit, and/or a radio component), a display projector component, a graphics processor, and/or a sensor (such as an inertial measurement sensor).

(A11) In some embodiments of any of A1-A10, the byproduct heat is transferred to a location on the first temple arm that is configured to not be in contact with skin of a user. In some embodiments, non-contact portions of the first temple arm and the lens frame are configured to operate at a maximum temperature of 51 degrees Celsius, and contact portions of the first temple arm and the lens frame are configured to operate at a maximum of 43 degrees Celsius.

(A12) In some embodiments of any of A1-A11, the location on the first temple arm that is configured to not be in contact with the skin of the user has a higher maximum surface temperature threshold than another location on the first temple arm that is configured to be in contact with the user, such as a location above a user's ear. For example, FIG. 3 illustrates a location on the first temple arm that is configures to be in contact with the user (second skin-contact region 314A).

(A13) In some embodiments of any of A1-A12, the maximum surface temperature threshold at the location on the first temple arm that is configured to not be in contact with the user is at least 20 degrees Celsius greater than the other location on the first temple arm that is configured to be in contact with the user. For example, FIG. 3 illustrates a chart 330 which shows the maximum surface temperature threshold at the location on the first temple arm that is configured to not be in contact with the user 337 is greater than the other location on the first temple arm that is configured to be in contact with the user 332.

(A14) In some embodiments of any of A1-A13, the one or more electrical components can actively adjust their respective TDP based on temperature measured at one or more locations on the first temple arm.

(A15) In some embodiments of any of A1-A14, the temperature measured at the one or more locations correspond to temperature hot spots on the first temple arm, and a temperature hot spot is a location where the maximum temperature limit is reached first.

(A16) In some embodiments of any of A1-A15, the one or more electrical components can actively adjust their feature set in stages based on temperature measured at one or more locations on the first temple arm. For example, a first set of features may be removed, and, if that does not resolve thermal concerns, then a second set of features may also be removed.

(A17) In some embodiments of any of A1-A16, the one or more electrical components actively adjust their respective TDP in accordance with a determination that the head-worn device is either located indoors or outdoors, or any other environmental condition that requires respective TDP to be reduced. In some embodiments, direct sun exposure will cause the first temple arm to increase in temperature, which lowers the amount of heat that can be dissipated by the first temple arm while trying to maintain its temperature maximum. In some embodiments, the maximum thermal design power for the head-worn device us 2000 mW when indoors. For example, FIGS. 5A-5B illustrate the head-worn device 110 located indoors and having a first TDP 524, and the head-worn device 110 located outdoors and having a second TDP 526.

(A18) In some embodiments of any of A1-A17, a portion of the first temple arm includes a thermal interface material that can be used to transfer heat to a surface of the first temple arm.

(A19) In some embodiments of any of A1-A18, the first temple arm is configured to dissipate heat by radiation, convection from surrounding air, and conduction into the user.

(A20) In some embodiments of any of A1-A19, the head-worn device further includes one or more additional electrical components and another heat-transfer component. The one or more additional electrical components are located within the first temple arm, and the one or more additional electrical components emit additional byproduct heat when operating. The other heat-transfer component is configured to transfer the additional byproduct heat from the one or more additional electrical components to the lens frame, and the transferring the additional byproduct heat from the one or more additional electronic components to the lens frame is configured to cause lengthening of a time duration during which the one or more additional electrical components can operate at their respective TDP. In some embodiments, the lengthening of the time duration allows the one or more additional electrical components to run for an extended period of 5-30 minutes instead of 5 seconds baes on environmental conditions. For example, FIG. 4 illustrates the head-worn device 110 including the one or more additional electrical components 422A, located within the first temple arm, and the other heat-transfer component (represented by arrows 430) configured to transfer the additional byproduct heat from the additional electrical components 422A to the lens frame 112.

(A21) In some embodiments of any of A1-A20, the head-worn device further includes one or more additional electrical components and another heat-transfer component. The one or more additional electrical components are located within the first temple arm, and the one or more additional electrical components emit additional byproduct heat when operating. The other heat-transfer component is configured to transfer the additional byproduct heat from the one or more additional electrical components to a second location on the lens frame. The second location on the lens frame is a location that is configured to be in minimal contact with skin of a user. The transferring of the additional byproduct heat from the one or more additional electronic components to the second location on the lens frame is configured to cause lengthening of a time duration during which the one or more additional electrical components can operate at their respective TDP. In some embodiments, the lengthening of the time duration allows the one or more additional electrical components to run for an extended period of 5-30 minutes instead of 5 seconds baes on environmental conditions.

(A22) In some embodiments of any of A1-A21, the heat-transfer component is a heat pipe, the first location is a location that corresponds with a nose bridge of a user, and the second location is a location that corresponds with an outer edge of the lens frame that is configured to not be in contact with the face of the user.

(A23) In some embodiments of any of A1-A22, the head-worn device further includes another heat-transfer component configured to transfer the byproduct heat from the one or more electrical components to one of the at least two lenses. The transferring of the byproduct heat from the one or more electrical components to the one of the at least two lenses is configured to cause lengthening of a time duration during which the one or more electrical component can operate at their respective TDP. In some embodiments, the lengthening of the time duration allows the one or more electrical components to run for an extended period of 5-30 minutes instead of 5 seconds baes on environmental conditions. For example, FIG. 4 illustrates the head-worn device 110 including the other heat-transfer component (represented by arrows 430) configured to transfer the byproduct heat from the one or more electrical components 122 and 422A-442B to one of the at least two lenses 416A-416B.

(A24) In some embodiments of any of A1-A23, the one of the at least two lenses is configured to spread the byproduct heat across a surface area of the one of the at least two lenses.

(A25) In some embodiments of any of A1-A24, the other heat-transfer component surrounds at least 50% of the perimeter of at least one of the at least two lenses. For example, FIG. 4 illustrates the other heat-transfer components 417A-417B surrounding the at least two lenses 416A-416B.

(A26) In some embodiments of any of A1-A25, the lens frame comprises of at least two rims to hold the at least two lenses in place, and the other heat-transfer component configured to transfer the byproduct heat from the one or more electrical components to one of the at least two lenses are at least partially located within the rims. In some embodiments, the other heat-transfer component includes one or more of a flexible heat pipe, graphite tape, and overmolded carbon tape. For example, FIG. 4 illustrates two rims 418A-418B to hold the two lenses 416A-416B, and the other heat-transfer component 417A-417B are, at least partially, located within the rims 418A-418B.

(B1) In accordance with some embodiments, a head-worn device includes a lens frame coupled to a hinged temple arm, and the hinged temple arm has an open state and a state other than open. The lens frame includes one or more waste heat emitting components and the hinged temple arm when the hinged temple arm is in the open state. The head-worn device is configured to have a first waste heat transfer rate between the one or more waste heat emitting components and the hinged temple arm when the hinged temple arm is in the open state. The head-worn device is configured to have a second waste heat transfer rate between the one or more waste heat emitting components and the hinged temple arm when the hinged temple arm is in the state other than the open state. The first heat transfer rate is greater than the second heat transfer rate. For example, FIG. 2A illustrates a lens frame 112 coupled to a hinged temple arm 114A with an open state 204 and a state other than open 202.

(B2) In some embodiments of B1, the lens frame includes a heat-transfer pad that is configured to connect to another heat transfer pad located in the hinged temple arm. The-heat transfer pad and the other heat-transfer pad are in contact when the hinged temple arm is in the open state. For example, FIG. 2A illustrates a first heat-transfer pad 212A that is configured to connect to another heat transfer pad 214A located in the hinged temple arm 114A.

(B3) In some embodiments of any of B1-B2, the heat-transfer pad and the other heat-transfer pad are made of a thermally conductive material that has a higher thermal conductivity than surrounding material that makes up the lens frame and hinged temple arm.

(B4) In some embodiments of any of B1-B3, the heat-transfer pad and the other heat-transfer pad are configured to have a 50 PSI contact force when the hinged temple arm is in the open state. The 50 PSI contact force is configured to increase the contact area between the heat-transfer pad and the other heat-transfer pad. In some embodiments, the heat-transfer pad and the other heat-transfer pad are configured to have anywhere from 20-100 PSI contact force when the hinged temple arm is in the open state.

(B5) In some embodiments of any of B1-B4, the heat-transfer pad and the other heat-transfer pad are made of substantially copper, or any other highly conductive material such as aluminum or an alloy.

(B6) In some embodiments of any of B1-B5, the other than open state includes a first subset of heat-transfer modalities, and the open state includes a second subset of heat-transfer modalities which includes (i) the first subset of heat-transfer modalities and (ii) the one or more additional heat-transfer modalities not included in the first subset of heat-transfer modalities.

(B7) In some embodiments of any of B1-B6, the first subset includes one or more of: (i) a flexible heat pipe, such as a vapor chamber, configured to transfer heat between the one or more waste heat emitting components and the hinged temple arm, where the flexible heat pipe is configured to transfer heat at the same rate when the hinged temple arm is in the open state or the other than open state, (ii) graphite tape configured to transfer heat between the one or more waste heat emitting components and the hinged temple arm, where the graphite tape is configured to transfer heat at the same rate when the hinged temple arm is in the open state or the other than open state, (iii) overmolded carbon tape configured to transfer heat between the one or more waste heat emitting components and the hinged temple arm, where the overmolded carbon tape is configured to transfer heat at the same rate when the hinged temple are is in the open state or the other than open state.

(B8) In some embodiments of any of B1-B7, the first subset is configured to be cycled at least 50,000 cycles, where one cycle is transitioning from the open state to the other than open state. In some embodiments, the first subset is configured to be cycled 20,000 to 75,000 cycles.

(B9) In some embodiments of any of B1-B8, the second subset includes a conductive hinge configured to transfer heat at a lower rate when the hinged temple arm is in the other than open state, and the conductive hinge is configured to transfer heat at a higher rate when the hinged temple arm is in the open state.

(B10) In some embodiments of any of B1-B9, the hinged temple arm is constructed of a polycarbonate material.

(B11) In some embodiments of any of B1-B10, the hinged temple arm is constructed of a magnesium material.

(C1) In accordance with some embodiments, a heat-transfer component is configured to transfer byproduct heat from one or more electrical components of a head-worn device to a first temple arm of the head-worn device. Transferring the byproduct heat from the one or more electrical components to the first temple arm is configured to cause a lengthening of a time duration during which the one or more electrical components can operate at their respective thermal design power. The byproduct heat is emitted by the one or more electrical components. The head-worn device includes a lens frame configured to hold at least two lenses in place, couple to the first temple arm via a hinge, and contain the one or more electrical components.

(C2) In some embodiments of C1, the heat-transfer component is configured for use with the features of the head-worn device of any of A2-A26.

(D1) In accordance with some embodiments, a heat-transfer component configured to have a first waste heat transfer rate between one or more waste heat emitting components of a head-worn device and a hinged temple arm of the head-worn device when the hinged temple arm is in an open state, and have a second waste heat transfer rate between the one or more waste heat emitting components and the hinged temple arm when the hinged temple arm is in a state other than the open state. The first heat transfer rate is greater than the second heat transfer rate. The head-worn device includes a lens frame, coupled to the hinged temple arm, including the one or more waste heat emitting components, and configured to transfer waste heat between the one or more waste heat emitting components and the hinged temple arm.

(D2) In some embodiments of D2, the heat-transfer component is configured for use with the features of the head-worn device of any of B1-B11.

The devices described above are further detailed below, including systems, wrist-wearable devices, headset devices, and smart textile-based garments. Specific operations described above may occur as a result of specific hardware, such hardware is described in further detail below. The devices described below are not limiting and features on these devices can be removed or additional features can be added to these devices. The different devices can include one or more analogous hardware components. For brevity, analogous devices and components are described below. Any differences in the devices and components are described below in their respective sections.

As described herein, a processor (e.g., a central processing unit (CPU), microcontroller unit (MCU), etc.), is an electronic component that is responsible for executing instructions and controlling the operation of an electronic device (e.g., a wrist-wearable device 700, a head-wearable device, an HIPD 900, a smart textile-based garment 1000, or other computer system). There are various types of processors that may be used interchangeably, or may be specifically required, by embodiments described herein. For example, a processor may be: (i) a general processor designed to perform a wide range of tasks, such as running software applications, managing operating systems, and performing arithmetic and logical operations; (ii) a microcontroller designed for specific tasks such as controlling electronic devices, sensors, and motors; (iii) a graphics processing unit (GPU) designed to accelerate the creation and rendering of images, videos, and animations (e.g., virtual-reality animations, such as three-dimensional modeling); (iv) a field-programmable gate array (FPGA) that can be programmed and reconfigured after manufacturing, and/or can be customized to perform specific tasks, such as signal processing, cryptography, and machine learning; (v) a digital signal processor (DSP) designed to perform mathematical operations on signals such as audio, video, and radio waves. One of skill in the art will understand that one or more processors of one or more electronic devices may be used in various embodiments described herein.

As described herein, controllers are electronic components that manage and coordinate the operation of other components within an electronic device (e.g., controlling inputs, processing data, and/or generating outputs). Examples of controllers can include: (i) microcontrollers, including small, low-power controllers that are commonly used in embedded systems and Internet of Things (IoT) devices; (ii) programmable logic controllers (PLCs) which may be configured to be used in industrial automation systems to control and monitor manufacturing processes; (iii) system-on-a-chip (SoC) controllers that integrate multiple components such as processors, memory, I/O interfaces, and other peripherals into a single chip; and/or DSPs. As described herein, a graphics module is a component or software module that is designed to handle graphical operations and/or processes, and can include a hardware module and/or a software module.

As described herein, memory refers to electronic components in a computer or electronic device that store data and instructions for the processor to access and manipulate. The devices described herein can include volatile and non-volatile memory. Examples of memory can include: (i) random access memory (RAM), such as DRAM, SRAM, DDR RAM or other random access solid state memory devices, configured to store data and instructions temporarily; (ii) read-only memory (ROM) configured to store data and instructions permanently (e.g., one or more portions of system firmware, and/or boot loaders); (iii) flash memory, magnetic disk storage devices, optical disk storage devices, other non-volatile solid state storage devices, which can be configured to store data in electronic devices (e.g., USB drives, memory cards, and/or solid-state drives (SSDs); and (iv) cache memory configured to temporarily store frequently accessed data and instructions. Memory, as described herein, can include structured data (e.g., SQL databases, MongoDB databases, GraphQL data, JSON data, etc.). Other examples of memory can include: (i) profile data, including user account data, user settings, and/or other user data stored by the user; (ii) sensor data detected and/or otherwise obtained by one or more sensors; (iii) media content data including stored image data, audio data, documents, and the like; (iv) application data, which can include data collected and/or otherwise obtained and stored during use of an application; and/or any other types of data described herein.

As described herein, a power system of an electronic device is configured to convert incoming electrical power into a form that can be used to operate the device. A power system can include various components, including: (i) a power source, which can be an alternating current (AC) adapter or a direct current (DC) adapter power supply; (ii) a charger input, and can be configured to use a wired and/or wireless connection (which may be part of a peripheral interface, such as a USB, micro-USB interface, near-field magnetic coupling, magnetic inductive and magnetic resonance charging, and/or radio frequency (RF) charging); (iii) a power-management integrated circuit, configured to distribute power to various components of the device and to ensure that the device operates within safe limits (e.g., regulating voltage, controlling current flow, and/or managing heat dissipation); and/or (iv) a battery configured to store power to provide usable power to components of one or more electronic devices.

As described herein, peripheral interfaces are electronic components (e.g., of electronic devices) that allow electronic devices to communicate with other devices or peripherals, and can provide a means for input and output of data and signals. Examples of peripheral interfaces can include: (i) universal serial bus (USB) and/or micro-USB interfaces configured for connecting devices to an electronic device; (ii) Bluetooth interfaces configured to allow devices to communicate with each other, including Bluetooth low energy (BLE); (iii) near field communication (NFC) interfaces configured to be short-range wireless interface for operations such as access control; (iv) POGO pins, which may be small, spring-loaded pins configured to provide a charging interface; (v) wireless charging interfaces; (vi) GPS interfaces; (vii) WiFi interfaces for providing a connection between a device and a wireless network; (viii) sensor interfaces.

As described herein, sensors are electronic components (e.g., in and/or otherwise in electronic communication with electronic devices, such as wearable devices) configured to detect physical and environmental changes and generate electrical signals. Examples of sensors can includer: (i) imaging sensors for collecting imaging data (e.g., including one or more cameras disposed on a respective electronic device); (ii) biopotential-signal sensors; (iii) inertial measurement unit (e.g., IMUs) for detecting, for example, angular rate, force, magnetic field, and/or changes in acceleration; (iv) heart rate sensors for measuring a user's heart rate; (v) SpO2 sensors for measuring blood oxygen saturation and/or other biometric data of a user; (vi) capacitive sensors for detecting changes in potential at a portion of a user's body (e.g., a sensor-skin interface) and/or the proximity of other devices or objects; (vii) light sensors (e.g., time-of-flight sensors, infrared light sensors, visible light sensors, etc.), and/or sensor for sensing data from the user or the user's environment. As described herein biopotential-signal-sensing components are devices used to measure electrical activity within the body (e.g., biopotential-signal sensors). Some types of biopotential-signal sensors include: (i) electroencephalography (EEG) sensors configured to measure electrical activity in the brain to diagnose neurological disorders; (ii) electrocardiogra (ECG or EKG) sensors configured to measure electrical activity of the heart to diagnose heart problems; (iii) electromyography (EMG) sensors configured to measure the electrical activity of muscles and to diagnose neuromuscular disorders; (iv) electrooculography (EOG) sensors configure to measure the electrical activity of eye muscles to detect eye movement and diagnose eye disorders.

As described herein, an application stored in memory of an electronic device (e.g., software) includes instructions stored in the memory. Examples of such applications include: (i) games; (ii) word processors; (iii) messaging applications; (iv) media-streaming applications; (v) financial applications; (vi) calendars; (vii) clocks; (viii) web-browsers; (ix) social media applications, (x) camera applications, (xi) web-based applications; (xii) health applications; (xiii) artificial reality applications, and/or any other applications that can be stored in memory. The applications can operate in conjunction with data and/or one or more components of a device or communicatively coupled devices to perform one or more operations and/or functions.

As described herein, communication interface modules can include hardware and/or software capable of data communications using any of a variety of custom or standard wireless protocols (e.g., IEEE 802.15.4, Wi-Fi, ZigBee, 6LoWPAN, Thread, Z-Wave, Bluetooth Smart, ISA100.11a, WirelessHART, or MiWi), custom or standard wired protocols (e.g., Ethernet or HomePlug), and/or any other suitable communication protocol, including communication protocols not yet developed as of the filing date of this document. A communication interface is a mechanism that enables different systems or devices to exchange information and data with each other, including hardware, software, or a combination of both hardware and software. For example, a communication interface can refer to a physical connector and/or port on a device that enables communication with other devices (e.g., USB, Ethernet, HDMI, Bluetooth). In some embodiments, a communication interface can refer to a software layer that enables different software programs to communicate with each other (e.g., application programming interfaces (APIs), protocols like HTTP and TCP/IP, etc.).

As described herein, a graphics module is a component or software module that is designed to handle graphical operations and/or processes, and can include a hardware module and/or a software module.

As described herein, non-transitory computer-readable storage media are physical devices or storage medium that can be used to store electronic data in a non-transitory form (e.g., such that the data is stored permanently until it is intentionally deleted or modified.

### Example AR Systems 6A-6C-2

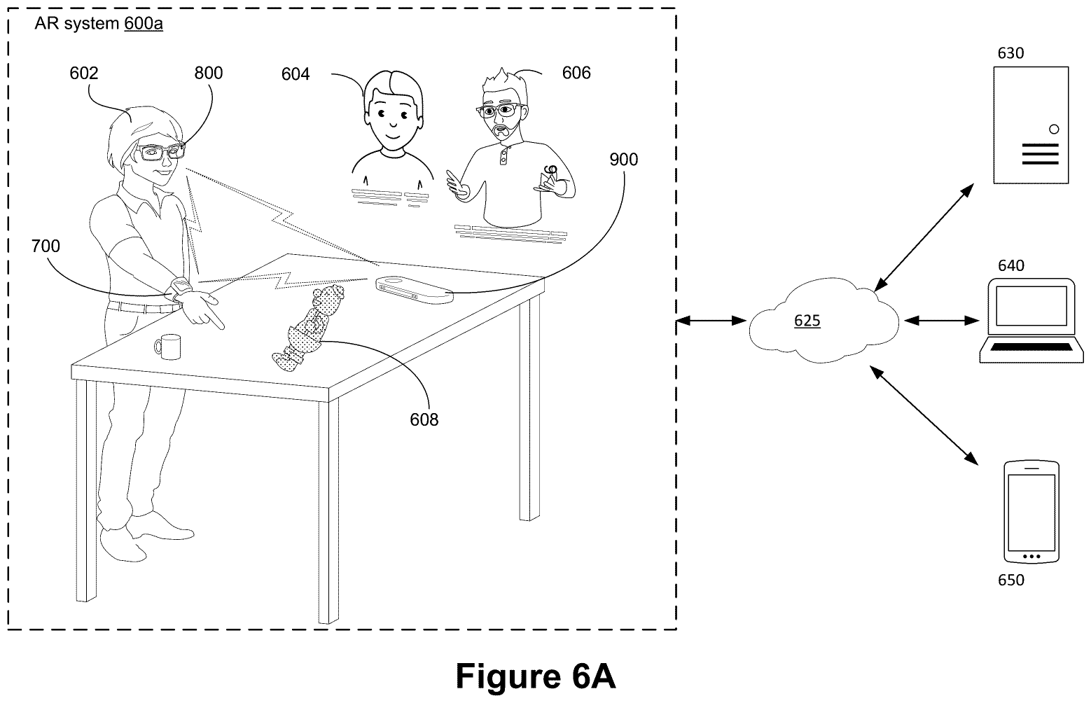

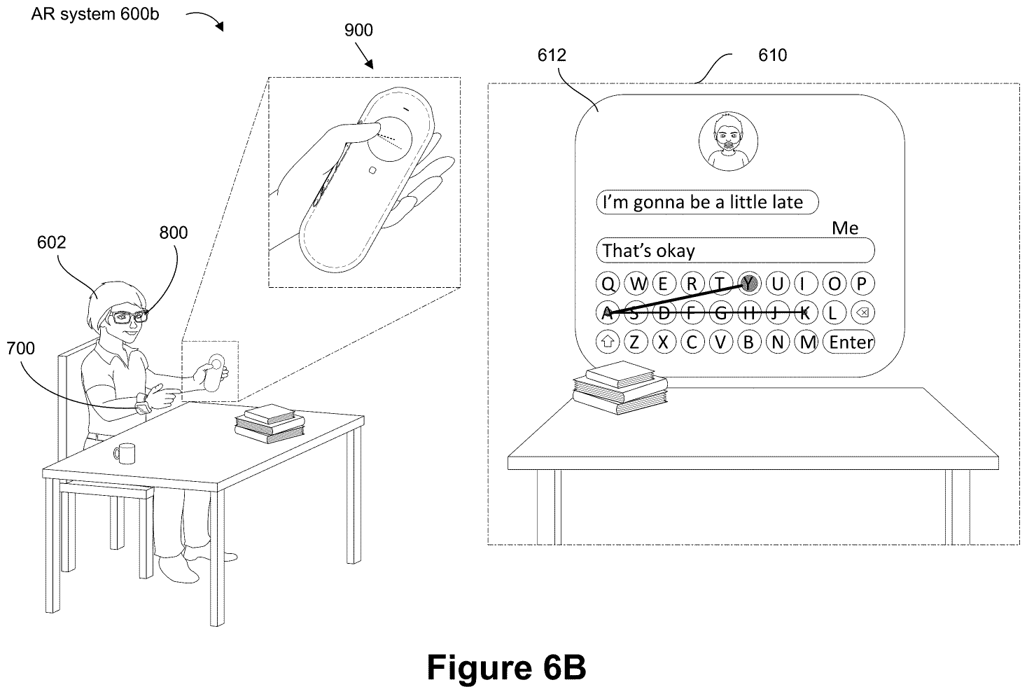

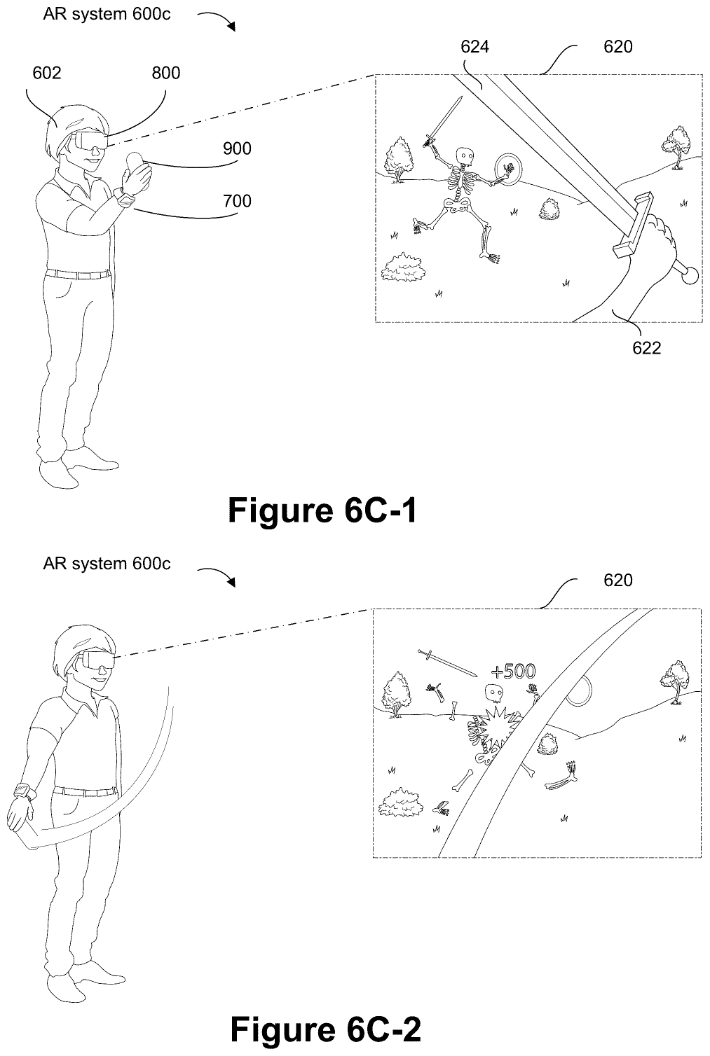

FIGS. 6A-6C2 illustrate example artificial-reality systems, in accordance with some embodiments. FIG. 6A shows a first AR system 600a and first example user interactions using a wrist-wearable device 700, a head-wearable device (e.g., AR device 800), and/or a handheld intermediary processing device (HIPD) 900. FIG. 6B shows a second AR system 600b and second example user interactions using a wrist-wearable device 700, AR device 800, and/or an HIPD 900. FIGS. 6C-1 and 6C-2 show a third AR system 600c and third example user interactions using a wrist-wearable device 700, a head-wearable device (e.g., VR device 810), and/or an HIPD 900. As the skilled artisan will appreciate upon reading the descriptions provided herein, the above-example AR systems (described in detail below) can perform various functions and/or operations described above with reference to FIGS. 1-5B.

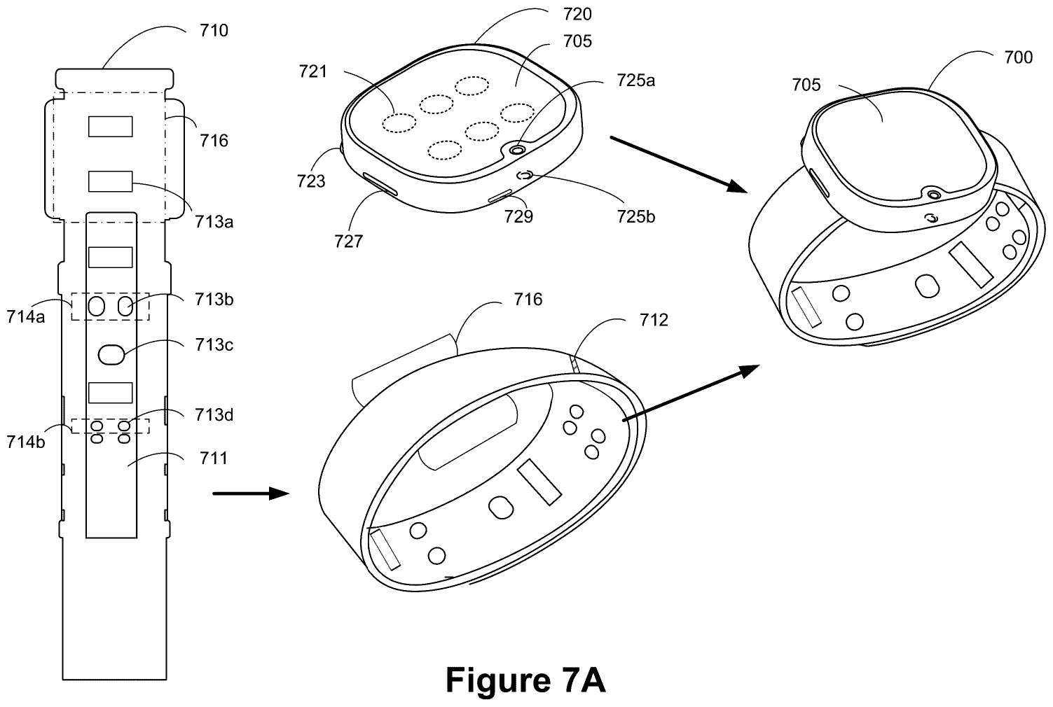

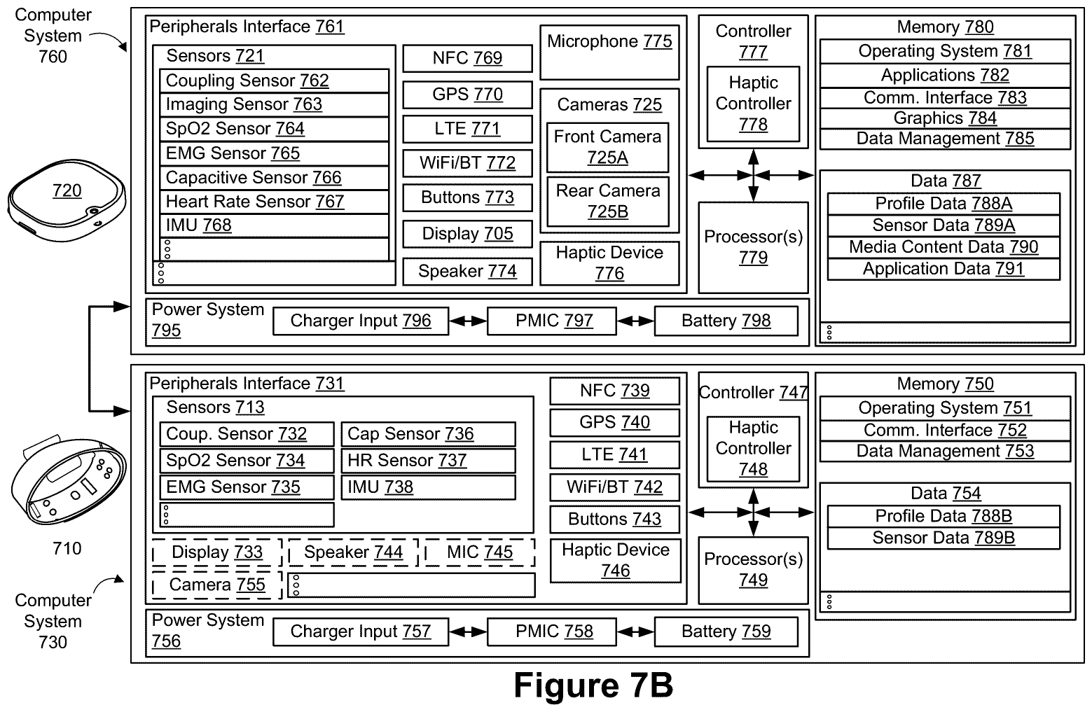

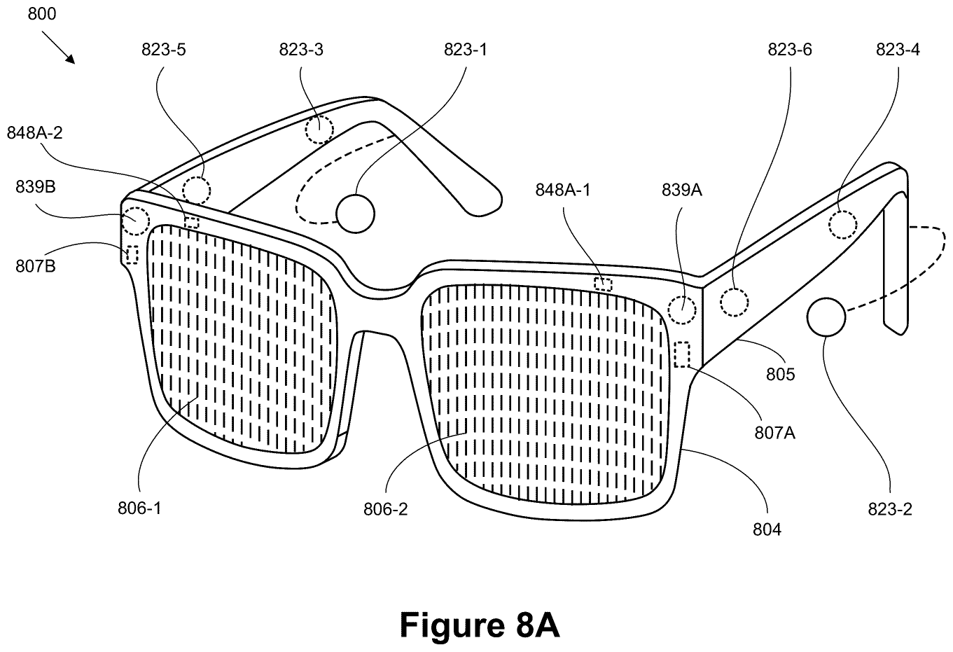

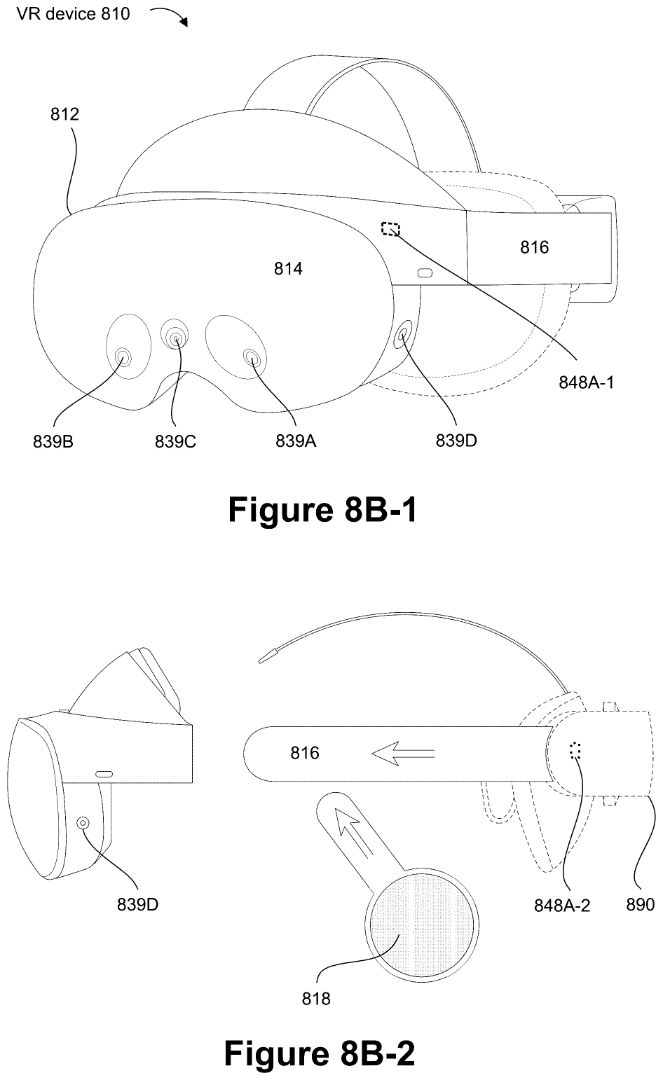

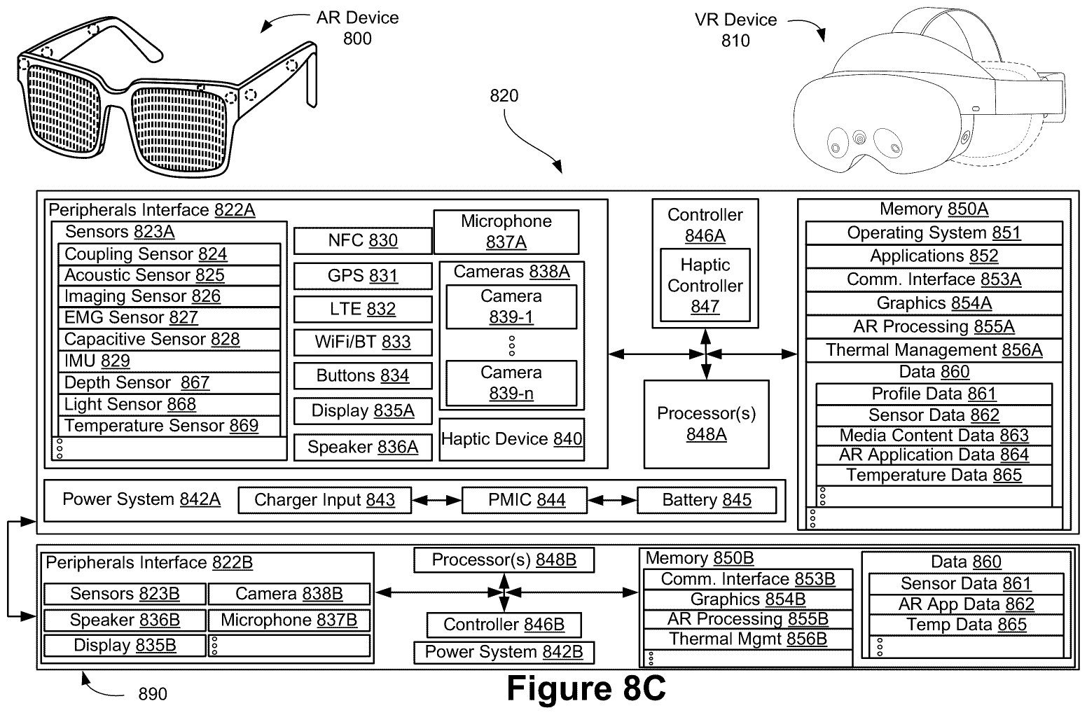

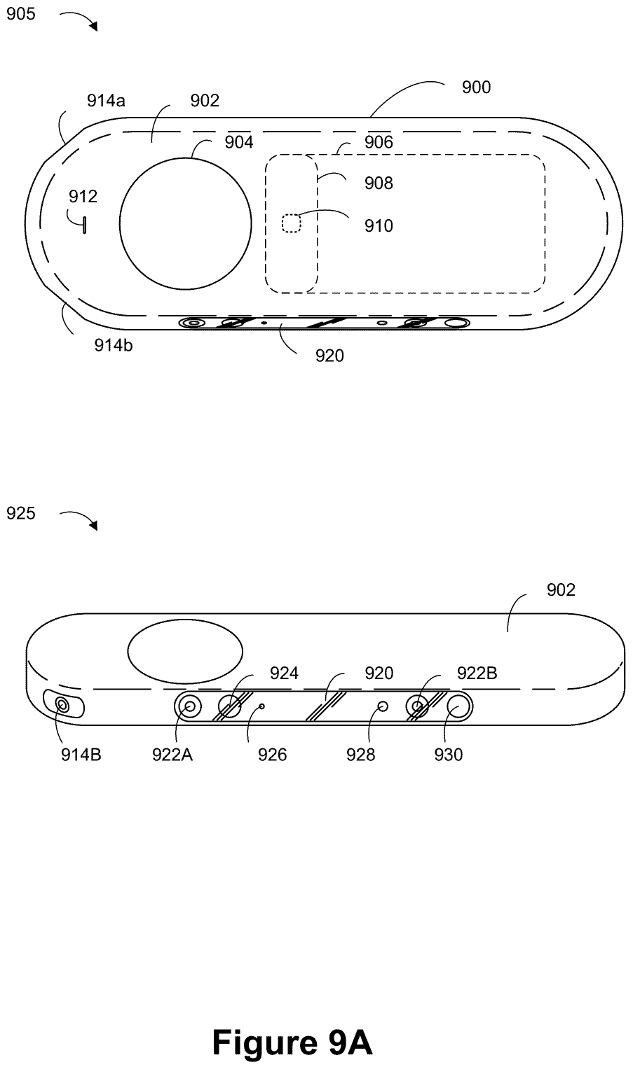

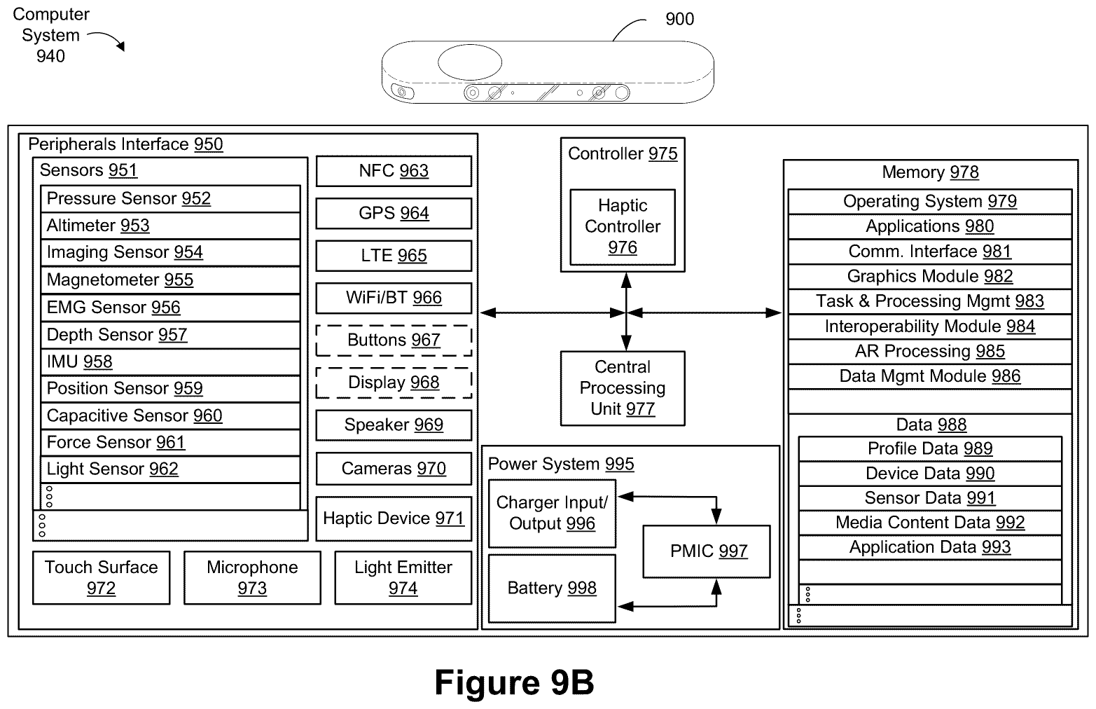

The wrist-wearable device 700 and one or more of its components are described below in reference to FIGS. 7A-7B; the head-wearable devices and their one or more components are described below in reference to FIGS. 8A-8D; and the HIPD 900 and its one or more components are described below in reference to FIGS. 9A-9B. The wrist-wearable device 700, the head-wearable devices, and/or the HIPD 900 can communicatively couple via a network 625 (e.g., cellular, near field, Wi-Fi, personal area network, wireless LAN, etc.). Additionally, the wrist-wearable device 700, the head-wearable devices, and/or the HIPD 900 can also communicatively couple with one or more servers 630, computers 640 (e.g., laptops, computers, etc.), mobile devices 650 (e.g., smartphones, tablets, etc.), and/or other electronic devices via the network 625 (e.g., cellular, near field, Wi-Fi, personal area network, wireless LAN, etc.).

Turning to FIG. 6A, a user 602 is shown wearing the wrist-wearable device 700 and the AR device 800, and having the HIPD 900 on their desk. The wrist-wearable device 700, the AR device 800, and the HIPD 900 facilitate user interaction with an AR environment. In particular, as shown by the first AR system 600a, the wrist-wearable device 700, the AR device 800, and/or the HIPD 900 cause presentation of one or more avatars 604, digital representations of contacts 606, and virtual objects 608. As discussed below, the user 602 can interact with the one or more avatars 604, digital representations of the contacts 606, and virtual objects 608 via the wrist-wearable device 700, the AR device 800, and/or the HIPD 900.

The user 602 can use any of the wrist-wearable device 700, the AR device 800, and/or the HIPD 900 to provide user inputs. For example, the user 602 can perform one or more hand gestures that are detected by the wrist-wearable device 700 (e.g., using one or more EMG sensors and/or IMUs, described below in reference to FIGS. 7A-7B) and/or AR device 800 (e.g. using one or more image sensor or camera, described below in reference to FIGS. 8A-8B) to provide a user input. Alternatively, or additionally, the user 602 can provide a user input via one or more touch surfaces of the wrist-wearable device 700, the AR device 800, and/or the HIPD 900, and/or voice commands captured by a microphone of the wrist-wearable device 700, the AR device 800, and/or the HIPD 900. In some embodiments, the wrist-wearable device 700, the AR device 800, and/or the HIPD 900 include a digital assistant to help the user in providing a user input (e.g., completing a sequence of operations, suggesting different operations or commands, providing reminders, confirming a command, etc.). In some embodiments, the user 602 can provide a user input via one or more facial gestures and/or facial expressions. For example, cameras of the wrist-wearable device 700, the AR device 800, and/or the HIPD 900 can track the user 602's eyes for navigating a user interface.

The wrist-wearable device 700, the AR device 800, and/or the HIPD 900 can operate alone or in conjunction to allow the user 602 to interact with the AR environment. In some embodiments, the HIPD 900 is configured to operate as a central hub or control center for the wrist-wearable device 700, the AR device 800, and/or another communicatively coupled device. For example, the user 602 can provide an input to interact with the AR environment at any of the wrist-wearable device 700, the AR device 800, and/or the HIPD 900, and the HIPD 900 can identify one or more back-end and front-end tasks to cause the performance of the requested interaction and distribute instructions to cause the performance of the one or more back-end and front-end tasks at the wrist-wearable device 700, the AR device 800, and/or the HIPD 900. In some embodiments, a back-end task is background processing task that is not perceptible by the user (e.g., rendering content, decompression, compression, etc.), and a front-end task is a user-facing task that is perceptible to the user (e.g., presenting information to the user, providing feedback to the user, etc.)). As described below in reference to FIGS. 9A-9B, the HIPD 900 can perform the back-end tasks and provide the wrist-wearable device 700 and/or the AR device 800 operational data corresponding to the performed back-end tasks such that the wrist-wearable device 700 and/or the AR device 800 can perform the front-end tasks. In this way, the HIPD 900, which has more computational resources and greater thermal headroom than the wrist-wearable device 700 and/or the AR device 800, performs computationally intensive tasks and reduces the computer resource utilization and/or power usage of the wrist-wearable device 700 and/or the AR device 800.

In the example shown by the first AR system 600a, the HIPD 900 identifies one or more back-end tasks and front-end tasks associated with a user request to initiate an AR video call with one or more other users (represented by the avatar 604 and the digital representation of the contact 606) and distributes instructions to cause the performance of the one or more back-end tasks and front-end tasks. In particular, the HIPD 900 performs back-end tasks for processing and/or rendering image data (and other data) associated with the AR video call and provides operational data associated with the performed back-end tasks to the AR device 800 such that the AR device 800 perform front-end tasks for presenting the AR video call (e.g., presenting the avatar 604 and the digital representation of the contact 606).

In some embodiments, the HIPD 900 can operate as a focal or anchor point for causing the presentation of information. This allows the user 602 to be generally aware of where information is presented. For example, as shown in the first AR system 600a, the avatar 604 and the digital representation of the contact 606 are presented above the HIPD 900. In particular, the HIPD 900 and the AR device 800 operate in conjunction to determine a location for presenting the avatar 604 and the digital representation of the contact 606. In some embodiments, information can be presented a predetermined distance from the HIPD 900 (e.g., within 5 meters). For example, as shown in the first AR system 600a, virtual object 608 is presented on the desk some distance from the HIPD 900. Similar to the above example, the HIPD 900 and the AR device 800 can operate in conjunction to determine a location for presenting the virtual object 608. Alternatively, in some embodiments, presentation of information is not bound by the HIPD 900. More specifically, the avatar 604, the digital representation of the contact 606, and the virtual object 608 do not have to be presented within a predetermined distance of the HIPD 900.

User inputs provided at the wrist-wearable device 700, the AR device 800, and/or the HIPD 900 are coordinated such that the user can use any device to initiate, continue, and/or complete an operation. For example, the user 602 can provide a user input to the AR device 800 to cause the AR device 800 to present the virtual object 608 and, while the virtual object 608 is presented by the AR device 800, the user 602 can provide one or more hand gestures via the wrist-wearable device 700 to interact and/or manipulate the virtual object 608.

FIG. 6B shows the user 602 wearing the wrist-wearable device 700 and the AR device 800, and holding the HIPD 900. In the second AR system 600b, the wrist-wearable device 700, the AR device 800, and/or the HIPD 900 are used to receive and/or provide one or more messages to a contact of the user 602. In particular, the wrist-wearable device 700, the AR device 800, and/or the HIPD 900 detect and coordinate one or more user inputs to initiate a messaging application and prepare a response to a received message via the messaging application.

In some embodiments, the user 602 initiates, via a user input, an application on the wrist-wearable device 700, the AR device 800, and/or the HIPD 900 that causes the application to initiate on at least one device. For example, in the second AR system 600b the user 602 performs a hand gesture associated with a command for initiating a messaging application (represented by messaging user interface 612); the wrist-wearable device 700 detects the hand gesture; and, based on a determination that the user 602 is wearing AR device 800, causes the AR device 800 to present a messaging user interface 612 of the messaging application. The AR device 800 can present the messaging user interface 612 to the user 602 via its display (e.g., as shown by user 602's field of view 610). In some embodiments, the application is initiated and ran on the device (e.g., the wrist-wearable device 700, the AR device 800, and/or the HIPD 900) that detects the user input to initiate the application, and the device provides another device operational data to cause the presentation of the messaging application. For example, the wrist-wearable device 700 can detect the user input to initiate a messaging application; initiate and run the messaging application; and provide operational data to the AR device 800 and/or the HIPD 900 to cause presentation of the messaging application. Alternatively, the application can be initiated and ran at a device other than the device that detected the user input. For example, the wrist-wearable device 700 can detect the hand gesture associated with initiating the messaging application and cause the HIPD 900 to run the messaging application and coordinate the presentation of the messaging application.

Further, the user 602 can provide a user input provided at the wrist-wearable device 700, the AR device 800, and/or the HIPD 900 to continue and/or complete an operation initiated are at another device. For example, after initiating the messaging application via the wrist-wearable device 700 and while the AR device 800 present the messaging user interface 612, the user 602 can provide an input at the HIPD 900 to prepare a response (e.g., shown by the swipe gesture performed on the HIPD 900). The user 602's gestures performed on the HIPD 900 can be provided and/or displayed on another device. For example, the user 602's swipe gestured performed on the HIPD 900 are displayed on a virtual keyboard of the messaging user interface 612 displayed by the AR device 800.

In some embodiments, the wrist-wearable device 700, the AR device 800, the HIPD 900, and/or other communicatively couple device can present one or more notifications to the user 602. The notification can be an indication of a new message, an incoming call, an application update, a status update, etc. The user 602 can select the notification via the wrist-wearable device 700, the AR device 800, the HIPD 900, and cause presentation of an application or operation associated with the notification on at least one device. For example, the user 602 can receive a notification that a message was received at the wrist-wearable device 700, the AR device 800, the HIPD 900, and/or other communicatively couple device and provide a user input at the wrist-wearable device 700, the AR device 800, and/or the HIPD 900 to review the notification, and the device detecting the user input can cause an application associated with the notification to be initiated and/or presented at the wrist-wearable device 700, the AR device 800, and/or the HIPD 900.

While the above example describes coordinated inputs used to interact with a messaging application, the skilled artisan will appreciate upon reading the descriptions that user inputs can be coordinated to interact with any number of applications including, but not limited to, gaming applications, social media applications, camera applications, web-based applications, financial applications, etc. For example, the AR device 800 can present to the user 602 game application data and the HIPD 900 can use a controller to provide inputs to the game. Similarly, the user 602 can use the wrist-wearable device 700 to initiate a camera of the AR device 800, and the user can use the wrist-wearable device 700, the AR device 800, and/or the HIPD 900 to manipulate the image capture (e.g., zoom in or out, apply filters, etc.) and capture image data.

Turning to FIGS. 6C-1 and 6C-2, the user 602 is shown wearing the wrist-wearable device 700 and a VR device 810, and holding the HIPD 900. In the third AR system 600c, the wrist-wearable device 700, the VR device 810, and/or the HIPD 900 are used to interact within an AR environment, such as a VR game or other AR application. While the VR device 810 present a representation of a VR game (e.g., first AR game environment 620) to the user 602, the wrist-wearable device 700, the VR device 810, and/or the HIPD 900 detect and coordinate one or more user inputs to allow the user 602 to interact with the VR game.

In some embodiments, the user 602 can provide a user input via the wrist-wearable device 700, the VR device 810, and/or the HIPD 900 that causes an action in a corresponding AR environment. For example, the user 602 in the third AR system 600c (shown in FIG. 6C-1) raises the HIPD 900 to prepare for a swing in the first AR game environment 620. The VR device 810, responsive to the user 602 raising the HIPD 900, causes the AR representation of the user 622 to perform a similar action (e.g., raise a virtual object, such as a virtual sword 624). In some embodiments, each device uses respective sensor data and/or image data to detect the user input and provide an accurate representation of the user 602's motion. For example, image sensors 958 (e.g., SLAM cameras or other cameras discussed below in FIGS. 9A and 9B) of the HIPD 900 can be used to detect a position of the 900 relative to the user 602's body such that the virtual object can be positioned appropriately within the first AR game environment 620; sensor data from the wrist-wearable device 700 can be used to detect a velocity at which the user 602 raises the HIPD 900 such that the AR representation of the user 622 and the virtual sword 624 are synchronized with the user 602's movements; and image sensors 826 (FIGS. 8A-8C) of the VR device 810 can be used to represent the user 602's body, boundary conditions, or real-world objects within the first AR game environment 620.

In FIG. 6C-2, the user 602 performs a downward swing while holding the HIPD 900. The user 602's downward swing is detected by the wrist-wearable device 700, the VR device 810, and/or the HIPD 900 and a corresponding action is performed in the first AR game environment 620. In some embodiments, the data captured by each device is used to improve the user's experience within the AR environment. For example, sensor data of the wrist-wearable device 700 can be used to determine a speed and/or force at which the downward swing is performed and image sensors of the HIPD 900 and/or the VR device 810 can be used to determine a location of the swing and how it should be represented in the first AR game environment 620, which, in turn, can be used as inputs for the AR environment (e.g., game mechanics, which can use detected speed, force, locations, and/or aspects of the user 602's actions to classify a user's inputs (e.g., user performs a light strike, hard strike, critical strike, glancing strike, miss, etc.) or calculate an output (e.g., amount of damage)).

While the wrist-wearable device 700, the VR device 810, and/or the HIPD 900 are described as detecting user inputs, in some embodiments, user inputs are detected at a single device (with the single device being responsible for distributing signals to the other devices for performing the user input). For example, the HIPD 900 can operate an application for generating the first AR game environment 620 and provide the VR device 810 with corresponding data for causing the presentation of the first AR game environment 620, as well as detect the 602's movements (while holding the HIPD 900) to cause the performance of corresponding actions within the first AR game environment 620. Additionally or alternatively, in some embodiments, operational data (e.g., sensor data, image data, application data, device data, and/or other data) of one or more devices is provide to a single device (e.g., the HIPD 900) to process the operational data and cause respective devices to perform an action associated with processed operational data.

Having discussed example AR systems, devices for interacting with such AR systems, and other computing systems more generally, will now be discussed in greater detail below. Some definitions of devices and components that can be included in some or all of the example devices discussed below are defined here for case of reference. A skilled artisan will appreciate that certain types of the components described below may be more suitable for a particular set of devices, and less suitable for a different set of devices. But subsequent reference to the components defined here should be considered to be encompassed by the definitions provided.

In some embodiments discussed below example devices and systems, including electronic devices and systems, will be discussed. Such example devices and systems are not intended to be limiting, and one of skill in the art will understand that alternative devices and systems to the example devices and systems described herein may be used to perform the operations and construct the systems and device that are described herein.

As described herein, an electronic device is a device that uses electrical energy to perform a specific function. It can be any physical object that contains electronic components such as transistors, resistors, capacitors, diodes, and integrated circuits. Examples of electronic devices include smartphones, laptops, digital cameras, televisions, gaming consoles, and music players, as well as the example electronic devices discussed herein. As described herein, an intermediary electronic device is a device that sits between two other electronic devices, and/or a subset of components of one or more electronic devices and facilitates communication, and/or data processing and/or data transfer between the respective electronic devices and/or electronic components.

### Example Wrist-Wearable Devices

FIGS. 7A and 7B illustrate an example wrist-wearable device 700, in accordance with some embodiments. FIG. 7A illustrates components of the wrist-wearable device 700, which can be used individually or in combination, including combinations that include other electronic devices and/or electronic components.

FIG. 7A shows a wearable band 710 and a watch body 720 (or capsule) being coupled, as discussed below, to form the wrist-wearable device 700. The wrist-wearable device 700 can perform various functions and/or operations associated with navigating through user interfaces and selectively opening applications, as well as the functions and/or operations.

As will be described in more detail below, operations executed by the wrist-wearable device 700 can include: (i) presenting content to a user (e.g., displaying visual content via a display 705); (ii) detecting (e.g., sensing) user input (e.g., sensing a touch on peripheral button 723 and/or at a touch screen of the display 705, a hand gesture detected by sensors (e.g., biopotential sensors)); (iii) sensing biometric data via one or more sensors 713 (e.g., neuromuscular signals, heart rate, temperature, sleep, etc.); messaging (e.g., text, speech, video, etc.); image capture via one or more imaging devices or cameras 725; wireless communications (e.g., cellular, near field, Wi-Fi, personal area network, etc.); location determination; financial transactions; providing haptic feedback; alarms; notifications; biometric authentication; health monitoring; sleep monitoring; etc.

The above-example functions can be executed independently in the watch body 720, independently in the wearable band 710, and/or via an electronic communication between the watch body 720 and the wearable band 710. In some embodiments, functions can be executed on the wrist-wearable device 700 while an AR environment is being presented (e.g., via one of the AR systems 600a to 600d). As the skilled artisan will appreciate upon reading the descriptions provided herein, the novel wearable devices described herein can be used with other types of AR environments.

The wearable band 710 can be configured to be worn by a user such that an inner (or inside) surface of the wearable structure 711 of the wearable band 710 is in contact with the user's skin. When worn by a user, sensors 713 contact the user's skin. The sensors 713 can sense biometric data such as a user's heart rate, saturated oxygen level, temperature, sweat level, neuromuscular signal sensors, or a combination thereof. The sensors 713 can also sense data about a user's environment including a user's motion, altitude, location, orientation, gait, acceleration, position, or a combination thereof. In some embodiment, the sensors 713 are configured to track a position and/or motion of the wearable band 710. The one or more sensors 713 can include any of the sensors defined above and/or discussed below with respect to FIG. 7B.

The one or more sensors 713 can be distributed on an inside and/or an outside surface of the wearable band 710. In some embodiments, the one or more sensors 713 are uniformly spaced along the wearable band 710. Alternatively, in some embodiments, the one or more sensors 713 are positioned at distinct points along the wearable band 710. As shown in FIG. 7A, the one or more sensors 713 can be the same or distinct. For example, in some embodiments, the one or more sensors 713 can be shaped as a pill (e.g., sensor 713a), an oval, a circle a square, an oblong (e.g., sensor 713c) and/or any other shape that maintains contact with the user's skin (e.g., such that neuromuscular signal and/or other biometric data can be accurately measured at the user's skin). In some embodiments, the one or more sensors 713 are aligned to form pairs of sensors (e.g., for sensing neuromuscular signals based on differential sensing within each respective sensor). For example, sensor 713b is aligned with an adjacent sensor to form sensor pair 714a and sensor 713d aligned with an adjacent sensor to form sensor pair 714b. In some embodiments, the wearable band 710 does not have a sensor pair. Alternatively, in some embodiments, the wearable band 710 has a predetermined number of sensor pairs (one pair of sensors, three pairs of sensors, four pairs of sensors, six pairs of sensors, sixteen pairs of sensors, etc.).

The wearable band 710 can include any suitable number of sensors 713. In some embodiments, the number and arrangement of sensors 713 depends on the particular application for which the wearable band 710 is used. For instance, a wearable band 710 configured as an armband, wristband, or chest-band may include a plurality of sensors 713 with different number of sensors 713 and different arrangement for each use case, such as medical use cases as compared to gaming or general day-to-day use cases.

In accordance with some embodiments, the wearable band 710 further includes an electrical ground electrode and a shielding electrode. The electrical ground and shielding electrodes, like the sensors 713, can be distributed on the inside surface of the wearable band 710 such that they contact a portion of the user's skin. For example, the electrical ground and shielding electrodes can be at an inside surface of coupling mechanism 716 or an inside surface of a wearable structure 711. The electrical ground and shielding electrodes can be formed and/or use the same components as the sensors 713. In some embodiments, the wearable band 710 includes more than one electrical ground electrode and more than one shielding electrode.

The sensors 713 can be formed as part of the wearable structure 711 of the wearable band 710. In some embodiments, the sensors 713 are flush or substantially flush with the wearable structure 711 such that they do not extend beyond the surface of the wearable structure 711. While flush with the wearable structure 711, the sensors 713 are still configured to contact the user's skin (e.g., via a skin-contacting surface). Alternatively, in some embodiments, the sensors 713 extend beyond the wearable structure 711 a predetermined distance (e.g., 0.1-2 mm) to make contact and depress into the user's skin. In some embodiment, the sensors 713 are coupled to an actuator (not shown) configured to adjust an extension height (e.g., a distance from the surface of the wearable structure 711) of the sensors 713 such that the sensors 713 make contact and depress into the user's skin. In some embodiments, the actuators adjust the extension height between 0.01 mm-1.2 mm. This allows the user to customize the positioning of the sensors 713 to improve the overall comfort of the wearable band 710 when worn while still allowing the sensors 713 to contact the user's skin. In some embodiments, the sensors 713 are indistinguishable from the wearable structure 711 when worn by the user.

The wearable structure 711 can be formed of an elastic material, elastomers, etc. configured to be stretched and fitted to be worn by the user. In some embodiments, the wearable structure 711 is a textile or woven fabric. As described above, the sensors 713 can be formed as part of a wearable structure 711. For example, the sensors 713 can be molded into the wearable structure 711 or be integrated into a woven fabric (e.g., the sensors 713 can be sewn into the fabric and mimic the pliability of fabric (e.g., the sensors 713 can be constructed from a series woven strands of fabric)).

The wearable structure 711 can include flexible electronic connectors that interconnect the sensors 713, the electronic circuitry, and/or other electronic components (described below in reference to FIG. 7B) that are enclosed in the wearable band 710. In some embodiments, the flexible electronic connectors are configured to interconnect the sensors 713, the electronic circuitry, and/or other electronic components of the wearable band 710 with respective sensors and/or other electronic components of another electronic device (e.g., watch body 720). The flexible electronic connectors are configured to move with the wearable structure 711 such that the user adjustment to the wearable structure 711 (e.g., resizing, pulling, folding, etc.) does not stress or strain the electrical coupling of components of the wearable band 710.

As described above, the wearable band 710 is configured to be worn by a user. In particular, the wearable band 710 can be shaped or otherwise manipulated to be worn by a user. For example, the wearable band 710 can be shaped to have a substantially circular shape such that it can be configured to be worn on the user's lower arm or wrist. Alternatively, the wearable band 710 can be shaped to be worn on another body part of the user, such as the user's upper arm (e.g., around a bicep), forearm, chest, legs, etc. The wearable band 710 can include a retaining mechanism 712 (e.g., a buckle, a hook and loop fastener, etc.) for securing the wearable band 710 to the user's wrist or other body part. While the wearable band 710 is worn by the user, the sensors 713 sense data (referred to as sensor data) from the user's skin. In particular, the sensors 713 of the wearable band 710 obtain (e.g., sense and record) neuromuscular signals.

The sensed data (e.g., sensed neuromuscular signals) can be used to detect and/or determine the user's intention to perform certain motor actions. In particular, the sensors 713 sense and record neuromuscular signals from the user as the user performs muscular activations (e.g., movements, gestures, etc.). The detected and/or determined motor actions (e.g., phalange (or digits) movements, wrist movements, hand movements, and/or other muscle intentions) can be used to determine control commands or control information (instructions to perform certain commands after the data is sensed) for causing a computing device to perform one or more input commands. For example, the sensed neuromuscular signals can be used to control certain user interfaces displayed on the display 705 of the wrist-wearable device 700 and/or can be transmitted to a device responsible for rendering an artificial-reality environment (e.g., a head-mounted display) to perform an action in an associated artificial-reality environment, such as to control the motion of a virtual device displayed to the user. The muscular activations performed by the user can include static gestures, such as placing the user's hand palm down on a table; dynamic gestures, such as grasping a physical or virtual object; and covert gestures that are imperceptible to another person, such as slightly tensing a joint by co-contracting opposing muscles or using sub-muscular activations. The muscular activations performed by the user can include symbolic gestures (e.g., gestures mapped to other gestures, interactions, or commands, for example, based on a gesture vocabulary that specifies the mapping of gestures to commands).

The sensor data sensed by the sensors 713 can be used to provide a user with an enhanced interaction with a physical object (e.g., devices communicatively coupled with the wearable band 710) and/or a virtual object in an artificial-reality application generated by an artificial-reality system (e.g., user interface objects presented on the display 705, or another computing device (e.g., a smartphone)).

In some embodiments, the wearable band 710 includes one or more haptic devices 746 (FIG. 7B; e.g., a vibratory haptic actuator) that are configured to provide haptic feedback (e.g., a cutaneous and/or kinesthetic sensation, etc.) to the user's skin. The sensors 713, and/or the haptic devices 746 can be configured to operate in conjunction with multiple applications including, without limitation, health monitoring, social media, games, and artificial reality (e.g., the applications associated with artificial reality).

The wearable band 710 can also include coupling mechanism 716 (e.g., a cradle or a shape of the coupling mechanism can correspond to shape of the watch body 720 of the wrist-wearable device 700) for detachably coupling a capsule (e.g., a computing unit) or watch body 720 (via a coupling surface of the watch body 720) to the wearable band 710. In particular, the coupling mechanism 716 can be configured to receive a coupling surface proximate to the bottom side of the watch body 720 (e.g., a side opposite to a front side of the watch body 720 where the display 705 is located), such that a user can push the watch body 720 downward into the coupling mechanism 716 to attach the watch body 720 to the coupling mechanism 716. In some embodiments, the coupling mechanism 716 can be configured to receive a top side of the watch body 720 (e.g., a side proximate to the front side of the watch body 720 where the display 705 is located) that is pushed upward into the cradle, as opposed to being pushed downward into the coupling mechanism 716. In some embodiments, the coupling mechanism 716 is an integrated component of the wearable band 710 such that the wearable band 710 and the coupling mechanism 716 are a single unitary structure. In some embodiments, the coupling mechanism 716 is a type of frame or shell that allows the watch body 720 coupling surface to be retained within or on the wearable band 710 coupling mechanism 716 (e.g., a cradle, a tracker band, a support base, a clasp, etc.).

The coupling mechanism 716 can allow for the watch body 720 to be detachably coupled to the wearable band 710 through a friction fit, magnetic coupling, a rotation-based connector, a shear-pin coupler, a retention spring, one or more magnets, a clip, a pin shaft, a hook and loop fastener, or a combination thereof. A user can perform any type of motion to couple the watch body 720 to the wearable band 710 and to decouple the watch body 720 from the wearable band 710. For example, a user can twist, slide, turn, push, pull, or rotate the watch body 720 relative to the wearable band 710, or a combination thereof, to attach the watch body 720 to the wearable band 710 and to detach the watch body 720 from the wearable band 710. Alternatively, as discussed below, in some embodiments, the watch body 720 can be decoupled from the wearable band 710 by actuation of the release mechanism 729.

The wearable band 710 can be coupled with a watch body 720 to increase the functionality of the wearable band 710 (e.g., converting the wearable band 710 into a wrist-wearable device 700, adding an additional computing unit and/or battery to increase computational resources and/or a battery life of the wearable band 710, adding additional sensors to improve sensed data, etc.). As described above, the wearable band 710 (and the coupling mechanism 716) is configured to operate independently (e.g., execute functions independently) from watch body 720. For example, the coupling mechanism 716 can include one or more sensors 713 that contact a user's skin when the wearable band 710 is worn by the user and provide sensor data for determining control commands.

A user can detach the watch body 720 (or capsule) from the wearable band 710 in order to reduce the encumbrance of the wrist-wearable device 700 to the user. For embodiments in which the watch body 720 is removable, the watch body 720 can be referred to as a removable structure, such that in these embodiments the wrist-wearable device 700 includes a wearable portion (e.g., the wearable band 710) and a removable structure (the watch body 720).

Turning to the watch body 720, the watch body 720 can have a substantially rectangular or circular shape. The watch body 720 is configured to be worn by the user on their wrist or on another body part. More specifically, the watch body 720 is sized to be easily carried by the user, attached on a portion of the user's clothing, and/or coupled to the wearable band 710 (forming the wrist-wearable device 700). As described above, the watch body 720 can have a shape corresponding to the coupling mechanism 716 of the wearable band 710. In some embodiments, the watch body 720 includes a single release mechanism 729 or multiple release mechanisms (e.g., two release mechanisms 729 positioned on opposing sides of the watch body 720, such as spring-loaded buttons) for decoupling the watch body 720 and the wearable band 710. The release mechanism 729 can include, without limitation, a button, a knob, a plunger, a handle, a lever, a fastener, a clasp, a dial, a latch, or a combination thereof.

A user can actuate the release mechanism 729 by pushing, turning, lifting, depressing, shifting, or performing other actions on the release mechanism 729. Actuation of the release mechanism 729 can release (e.g., decouple) the watch body 720 from the coupling mechanism 716 of the wearable band 710, allowing the user to use the watch body 720 independently from wearable band 710, and vice versa. For example, decoupling the watch body 720 from the wearable band 710 can allow the user to capture images using rear-facing camera 725B. Although the is shown positioned at a corner of watch body 720, the release mechanism 729 can be positioned anywhere on watch body 720 that is convenient for the user to actuate. In addition, in some embodiments, the wearable band 710 can also include a respective release mechanism for decoupling the watch body 720 from the coupling mechanism 716. In some embodiments, the release mechanism 729 is optional and the watch body 720 can be decoupled from the coupling mechanism 716 as described above (e.g., via twisting, rotating, etc.).

The watch body 720 can include one or more peripheral buttons 723 and 727 for performing various operations at the watch body 720. For example, the peripheral buttons 723 and 727 can be used to turn on or wake (e.g., transition from a sleep state to an active state) the display 705, unlock the watch body 720, increase or decrease a volume, increase or decrease a brightness, interact with one or more applications, interact with one or more user interfaces, etc. Additionally, or alternatively, in some embodiments, the display 705 operates as a touch screen and allows the user to provide one or more inputs for interacting with the watch body 720.

In some embodiments, the watch body 720 includes one or more sensors 721. The sensors 721 of the watch body 720 can be the same or distinct from the sensors 713 of the wearable band 710. The sensors 721 of the watch body 720 can be distributed on an inside and/or an outside surface of the watch body 720. In some embodiments, the sensors 721 are configured to contact a user's skin when the watch body 720 is worn by the user. For example, the sensors 721 can be placed on the bottom side of the watch body 720 and the coupling mechanism 716 can be a cradle with an opening that allows the bottom side of the watch body 720 to directly contact the user's skin. Alternatively, in some embodiments, the watch body 720 does not include sensors that are configured to contact the user's skin (e.g., including sensors internal and/or external to the watch body 720 that configured to sense data of the watch body 720 and the watch body 720's surrounding environment). In some embodiment, the sensors 713 are configured to track a position and/or motion of the watch body 720.

The watch body 720 and the wearable band 710 can share data using a wired communication method (e.g., a Universal Asynchronous Receiver/Transmitter (UART), a USB transceiver, etc.) and/or a wireless communication method (e.g., near field communication, Bluetooth, etc.). For example, the watch body 720 and the wearable band 710 can share data sensed by the sensors 713 and 721, as well as application and device specific information (e.g., active and/or available applications, output devices (e.g., display, speakers, etc.), input devices (e.g., touch screen, microphone, imaging sensors, etc.).

In some embodiments, the watch body 720 can include, without limitation, a front-facing camera 725A and/or a rear-facing camera 725B, sensors 721 (e.g., a biometric sensor, an IMU, a heart rate sensor, a saturated oxygen sensor, a neuromuscular signal sensor, an altimeter sensor, a temperature sensor, a bioimpedance sensor, a pedometer sensor, an optical sensor (e.g., imaging sensor 763; FIG. 7B), a touch sensor, a sweat sensor, etc.). In some embodiments, the watch body 720 can include one or more haptic devices 776 (FIG. 7B; a vibratory haptic actuator) that is configured to provide haptic feedback (e.g., a cutaneous and/or kinesthetic sensation, etc.) to the user. The sensors 721 and/or the haptic device 776 can also be configured to operate in conjunction with multiple applications including, without limitation, health monitoring applications, social media applications, game applications, and artificial reality applications (e.g., the applications associated with artificial reality).

As described above, the watch body 720 and the wearable band 710, when coupled, can form the wrist-wearable device 700. When coupled, the watch body 720 and wearable band 710 operate as a single device to execute functions (operations, detections, communications, etc.) described herein. In some embodiments, each device is provided with particular instructions for performing the one or more operations of the wrist-wearable device 700. For example, in accordance with a determination that the watch body 720 does not include neuromuscular signal sensors, the wearable band 710 can include alternative instructions for performing associated instructions (e.g., providing sensed neuromuscular signal data to the watch body 720 via a different electronic device). Operations of the wrist-wearable device 700 can be performed by the watch body 720 alone or in conjunction with the wearable band 710 (e.g., via respective processors and/or hardware components) and vice versa. In some embodiments, operations of the wrist-wearable device 700, the watch body 720, and/or the wearable band 710 can be performed in conjunction with one or more processors and/or hardware components of another communicatively coupled device (e.g., the HIPD 900; FIGS. 9A-9B).

As described below with reference to the block diagram of FIG. 7B, the wearable band 710 and/or the watch body 720 can each include independent resources required to independently execute functions. For example, the wearable band 710 and/or the watch body 720 can each include a power source (e.g., a battery), a memory, data storage, a processor (e.g., a central processing unit (CPU)), communications, a light source, and/or input/output devices.

FIG. 7B shows block diagrams of a computing system 730 corresponding to the wearable band 710, and a computing system 760 corresponding to the watch body 720, according to some embodiments. A computing system of the wrist-wearable device 700 includes a combination of components of the wearable band computing system 730 and the watch body computing system 760, in accordance with some embodiments.

The watch body 720 and/or the wearable band 710 can include one or more components shown in watch body computing system 760. In some embodiments, a single integrated circuit includes all or a substantial portion of the components of the watch body computing system 760 are included in a single integrated circuit. Alternatively, in some embodiments, components of the watch body computing system 760 are included in a plurality of integrated circuits that are communicatively coupled. In some embodiments, the watch body computing system 760 is configured to couple (e.g., via a wired or wireless connection) with the wearable band computing system 730, which allows the computing systems to share components, distribute tasks, and/or perform other operations described herein (individually or as a single device).

The watch body computing system 760 can include one or more processors 779, a controller 777, a peripherals interface 761, a power system 795, and memory (e.g., a memory 780), each of which are defined above and described in more detail below.

The power system 795 can include a charger input 796, a power-management integrated circuit (PMIC) 797, and a battery 798, each are which are defined above. In some embodiments, a watch body 720 and a wearable band 710 can have respective charger inputs (e.g., charger input 796 and 757), respective batteries (e.g., battery 798 and 759), and can share power with each other (e.g., the watch body 720 can power and/or charge the wearable band 710, and vice versa). Although watch body 720 and/or the wearable band 710 can include respective charger inputs, a single charger input can charge both devices when coupled. The watch body 720 and the wearable band 710 can receive a charge using a variety of techniques. In some embodiments, the watch body 720 and the wearable band 710 can use a wired charging assembly (e.g., power cords) to receive the charge. Alternatively, or in addition, the watch body 720 and/or the wearable band 710 can be configured for wireless charging. For example, a portable charging device can be designed to mate with a portion of watch body 720 and/or wearable band 710 and wirelessly deliver usable power to a battery of watch body 720 and/or wearable band 710. The watch body 720 and the wearable band 710 can have independent power systems (e.g., power system 795 and 756) to enable each to operate independently. The watch body 720 and wearable band 710 can also share power (e.g., one can charge the other) via respective PMICs (e.g., PMICs 797 and 758) that can share power over power and ground conductors and/or over wireless charging antennas.

In some embodiments, the peripherals interface 761 can include one or more sensors 721, many of which listed below are defined above. The sensors 721 can include one or more coupling sensor 762 for detecting when the watch body 720 is coupled with another electronic device (e.g., a wearable band 710). The sensors 721 can include imaging sensors 763 (one or more of the cameras 725, and/or separate imaging sensors 763 (e.g., thermal-imaging sensors)). In some embodiments, the sensors 721 include one or more SpO2 sensors 764. In some embodiments, the sensors 721 include one or more biopotential-signal sensors (e.g., EMG sensors 765, which may be disposed on a user-facing portion of the watch body 720 and/or the wearable band 710). In some embodiments, the sensors 721 include one or more capacitive sensors 766. In some embodiments, the sensors 721 include one or more heart rate sensors 767. In some embodiments, the sensors 721 include one or more IMUs 768. In some embodiments, one or more IMUs 768 can be configured to detect movement of a user's hand or other location that the watch body 720 is placed or held).

In some embodiments, the peripherals interface 761 includes a near-field communication (NFC) component 769, a global-position system (GPS) component 770, a long-term evolution (LTE) component 771, and/or a Wi-Fi and/or Bluetooth communication component 772. In some embodiments, the peripherals interface 761 includes one or more buttons 773 (e.g., the peripheral buttons 723 and 727 in FIG. 7A), which, when selected by a user, cause operation to be performed at the watch body 720. In some embodiments, the peripherals interface 761 includes one or more indicators, such as a light emitting diode (LED), to provide a user with visual indicators (e.g., message received, low battery, active microphone and/or camera, etc.).

The watch body 720 can include at least one display 705, for displaying visual representations of information or data to the user, including user-interface elements and/or three-dimensional virtual objects. The display can also include a touch screen for inputting user inputs, such as touch gestures, swipe gestures, and the like. The watch body 720 can include at least one speaker 774 and at least one microphone 775 for providing audio signals to the user and receiving audio input from the user. The user can provide user inputs through the microphone 775 and can also receive audio output from the speaker 774 as part of a haptic event provided by the haptic controller 778. The watch body 720 can include at least one camera 725, including a front-facing camera 725A and a rear-facing camera 725B. The cameras 725 can include ultra-wide-angle cameras, wide angle cameras, fish-eye cameras, spherical cameras, telephoto cameras, a depth-sensing cameras, or other types of cameras.

The watch body computing system 760 can include one or more haptic controllers 778 and associated componentry (e.g., haptic devices 776) for providing haptic events at the watch body 720 (e.g., a vibrating sensation or audio output in response to an event at the watch body 720). The haptic controllers 778 can communicate with one or more haptic devices 776, such as electroacoustic devices, including a speaker of the one or more speakers 774 and/or other audio components and/or electromechanical devices that convert energy into linear motion such as a motor, solenoid, electroactive polymer, piezoelectric actuator, electrostatic actuator, or other tactile output generating component (e.g., a component that converts electrical signals into tactile outputs on the device). The haptic controller 778 can provide haptic events to that are capable of being sensed by a user of the watch body 720. In some embodiments, the one or more haptic controllers 778 can receive input signals from an application of the applications 782.

In some embodiments, the computer system 730 and/or the computer system 760 can include memory 780, which can be controlled by a memory controller of the one or more controllers 777 and/or one or more processors 779. In some embodiments, software components stored in the memory 780 include one or more applications 782 configured to perform operations at the watch body 720. In some embodiments, the one or more applications 782 include games, word processors, messaging applications, calling applications, web browsers, social media applications, media streaming applications, financial applications, calendars, clocks, etc. In some embodiments, software components stored in the memory 780 include one or more communication interface modules 783 as defined above. In some embodiments, software components stored in the memory 780 include one or more graphics modules 784 for rendering, encoding, and/or decoding audio and/or visual data; and one or more data management modules 785 for collecting, organizing, and/or providing access to the data 787 stored in memory 780. In some embodiments, one or more of applications 782 and/or one or more modules can work in conjunction with one another to perform various tasks at the watch body 720.

In some embodiments, software components stored in the memory 780 can include one or more operating systems 781 (e.g., a Linux-based operating system, an Android operating system, etc.). The memory 780 can also include data 787. The data 787 can include profile data 788A, sensor data 789A, media content data 790, and application data 791.

It should be appreciated that the watch body computing system 760 is an example of a computing system within the watch body 720, and that the watch body 720 can have more or fewer components than shown in the watch body computing system 760, combine two or more components, and/or have a different configuration and/or arrangement of the components. The various components shown in watch body computing system 760 are implemented in hardware, software, firmware, or a combination thereof, including one or more signal processing and/or application-specific integrated circuits.

Turning to the wearable band computing system 730, one or more components that can be included in the wearable band 710 are shown. The wearable band computing system 730 can include more or fewer components than shown in the watch body computing system 760, combine two or more components, and/or have a different configuration and/or arrangement of some or all of the components. In some embodiments, all, or a substantial portion of the components of the wearable band computing system 730 are included in a single integrated circuit. Alternatively, in some embodiments, components of the wearable band computing system 730 are included in a plurality of integrated circuits that are communicatively coupled. As described above, in some embodiments, the wearable band computing system 730 is configured to couple (e.g., via a wired or wireless connection) with the watch body computing system 760, which allows the computing systems to share components, distribute tasks, and/or perform other operations described herein (individually or as a single device).

The wearable band computing system 730, similar to the watch body computing system 760, can include one or more processors 749, one or more controllers 747 (including one or more haptics controller 748), a peripherals interface 731 that can includes one or more sensors 713 and other peripheral devices, power source (e.g., a power system 756), and memory (e.g., a memory 750) that includes an operating system (e.g., an operating system 751), data (e.g., data 754 including profile data 788B, sensor data 789B, and one or more modules (e.g., a communications interface module 752, a data management module 753, etc.).

The one or more sensors 713 can be analogous to sensors 721 of the computer system 760 and in light of the definitions above. For example, sensors 713 can include one or more coupling sensors 732, one or more SpO2 sensor 734, one or more EMG sensors 735, one or more capacitive sensor 736, one or more heart rate sensor 737, and one or more IMU 738.

The peripherals interface 731 can also include other components analogous to those included in the peripheral interface 761 of the computer system 760, including an NFC component 739, a GPS component 740, an LTE component 741, a Wi-Fi and/or Bluetooth communication component 742, and/or one or more haptic devices 776 as described above in reference to peripherals interface 761. In some embodiments, the peripherals interface 731 includes one or more buttons 743, a display 733, a speaker 744, a microphone 745, and a camera 755. In some embodiments, the peripherals interface 731 includes one or more indicators, such as an LED.

It should be appreciated that the wearable band computing system 730 is an example of a computing system within the wearable band 710, and that the wearable band 710 can have more or fewer components than shown in the wearable band computing system 730, combine two or more components, and/or have a different configuration and/or arrangement of the components. The various components shown in wearable band computing system 730 can be implemented in one or a combination of hardware, software, firmware, including one or more signal processing and/or application-specific integrated circuits.

The wrist-wearable device 700 with respect to FIG. 7A is an example of the wearable band 710 and the watch body 720 coupled, so the wrist-wearable device 700 will be understood to include the components shown and described for the wearable band computing system 730 and the watch body computing system 760. In some embodiments, wrist-wearable device 700 has a split architecture (e.g., a split mechanical architecture, a split electrical architecture) between the watch body 720 and the wearable band 710. In other words, all of the components shown in the wearable band computing system 730 and the watch body computing system 760 can be housed or otherwise disposed in a combined watch device 700, or within individual components of the watch body 720, wearable band 710, and/or portions thereof (e.g., a coupling mechanism 716 of the wearable band 710).

The techniques described above can be used with any device for sensing neuromuscular signals, including the arm-wearable devices of FIG. 7A-7B, but could also be used with other types of wearable devices for sensing neuromuscular signals (such as body-wearable or head-wearable devices that might have neuromuscular sensors closer to the brain or spinal column).

In some embodiments, a wrist-wearable device 700 can be used in conjunction with a head-wearable device described below (e.g., AR device 800 and VR device 810) and/or an HIPD 900; and the wrist-wearable device 700 can also be configured to be used to allow a user to control aspect of the artificial reality (e.g., by using EMG-based gestures to control user interface objects in the artificial reality and/or by allowing a user to interact with the touchscreen on the wrist-wearable device to also control aspects of the artificial reality Having thus described example wrist-wearable device, attention will now be turned to example head-wearable devices, such AR device 800 and VR device 810.

### Example Head-Wearable Devices

FIGS. 8A-8C show example head-wearable devices, in accordance with some embodiments. Head-wearable devices can include, but are not limited to, AR devices 810 (e.g., AR or smart eyewear devices, such as smart glasses, smart monocles, smart contacts, etc.), VR devices 810 (e.g., VR headsets, head-mounted displays (HMD) s, etc.), or other ocularly coupled devices. The AR devices 800 and the VR devices 810 are instances of the head-worn device 110 described in reference to FIGS. 1-5B herein, such that the head-wearable device should be understood to have the features of the AR devices 800 and/or the VR devices 810, and vice versa. The AR devices 800 and the VR devices 810 can perform various functions and/or operations associated with navigating through user interfaces and selectively opening applications, as well as the functions and/or operations described above with reference to FIGS. 1-5B.

In some embodiments, an AR system (e.g., AR systems 600a-600d; FIGS. 6A-6D-2) includes an AR device 800 (as shown in FIG. 8A) and/or VR device 810 (as shown in FIGS. 8B-1-B-2). In some embodiments, the AR device 800 and the VR device 810 can include one or more analogous components (e.g., components for presenting interactive artificial-reality environments, such as processors, memory, and/or presentation devices, including one or more displays and/or one or more waveguides), some of which are described in more detail with respect to FIG. 8C. The head-wearable devices can use display projectors (e.g., display projector assemblies 807A and 807B) and/or waveguides for projecting representations of data to a user. Some embodiments of head-wearable devices do not include displays.

FIG. 8A shows an example visual depiction of the AR device 800 (e.g., which may also be described herein as augmented-reality glasses, and/or smart glasses). The AR device 800 can work in conjunction with additional electronic components that are not shown in FIGS. 8A, such as a wearable accessory device and/or an intermediary processing device, in electronic communication or otherwise configured to be used in conjunction with the AR device 800. In some embodiments, the wearable accessory device and/or the intermediary processing device may be configured to couple with the AR device 800 via a coupling mechanism in electronic communication with a coupling sensor 824, where the coupling sensor 824 can detect when an electronic device becomes physically or electronically coupled with the AR device 800. In some embodiments, the AR device 800 can be configured to couple to a housing (e.g., a portion of frame 804 or temple arms 805), which may include one or more additional coupling mechanisms configured to couple with additional accessory devices. The components shown in FIG. 8A can be implemented in hardware, software, firmware, or a combination thereof, including one or more signal-processing components and/or application-specific integrated circuits (ASICs).

The AR device 800 includes mechanical glasses components, including a frame 804 configured to hold one or more lenses (e.g., one or both lenses 806-1 and 806-2). One of ordinary skill in the art will appreciate that the AR device 800 can include additional mechanical components, such as hinges configured to allow portions of the frame 804 of the AR device 800 to be folded and unfolded, a bridge configured to span the gap between the lenses 806-1 and 806-2 and rest on the user's nose, nose pads configured to rest on the bridge of the nose and provide support for the AR device 800, earpieces configured to rest on the user's ears and provide additional support for the AR device 800, temple arms 805 configured to extend from the hinges to the earpieces of the AR device 800, and the like. One of ordinary skill in the art will further appreciate that some examples of the AR device 800 can include none of the mechanical components described herein. For example, smart contact lenses configured to present artificial-reality to users may not include any components of the AR device 800.

The lenses 806-1 and 806-2 can be individual displays or display devices (e.g., a waveguide for projected representations). The lenses 806-1 and 806-2 may act together or independently to present an image or series of images to a user. In some embodiments, the lenses 806-1 and 806-2 can operate in conjunction with one or more display projector assemblies 807A and 807B to present image data to a user. While the AR device 800 includes two displays, embodiments of this disclosure may be implemented in AR devices with a single near-eye display (NED) or more than two NEDs.

The AR device 800 includes electronic components, many of which will be described in more detail below with respect to FIG. 8C. Some example electronic components are illustrated in FIG. 8A, including sensors 823-1, 823-2, 823-3, 823-4, 823-5, and 823-6, which can be distributed along a substantial portion of the frame 804 of the AR device 800. The different types of sensors are described below in reference to FIG. 8C. The AR device 800 also includes a left camera 839A and a right camera 839B, which are located on different sides of the frame 804. And the eyewear device includes one or more processors 848A and 848B (e.g., an integral microprocessor, such as an ASIC) that is embedded into a portion of the frame 804.

FIGS. 8B-1 and 8B-2 show an example visual depiction of the VR device 810 (e.g., a head-mounted display (HMD) 812, also referred to herein as an artificial-reality headset, a head-wearable device, a VR headset, etc.). The HMD 812 includes a front body 814 and a frame 816 (e.g., a strap or band) shaped to fit around a user's head. In some embodiments, the front body 814 and/or the frame 816 includes one or more electronic elements for facilitating presentation of and/or interactions with an AR and/or VR system (e.g., displays, processors (e.g., processor 848A-1), IMUs, tracking emitter or detectors, sensors, etc.). In some embodiments, the HMD 812 includes output audio transducers (e.g., an audio transducer 818-1), as shown in FIG. 8B-2. In some embodiments, one or more components, such as the output audio transducer(s) 818 and the frame 816, can be configured to attach and detach (e.g., are detachably attachable) to the HMD 812 (e.g., a portion or all of the frame 816, and/or the output audio transducer 818), as shown in FIG. 8B-2. In some embodiments, coupling a detachable component to the HMD 812 causes the detachable component to come into electronic communication with the HMD 812. The VR device 810 includes electronic components, many of which will be described in more detail below with respect to FIG. 8C

FIG. 8B-1 to 8B-2 also show that the VR device 810 one or more cameras, such as the left camera 839A and the right camera 839B, which can be analogous to the left and right cameras on the frame 804 of the AR device 800. In some embodiments, the VR device 810 includes one or more additional cameras (e.g., cameras 839C and 839D), which can be configured to augment image data obtained by the cameras 839A and 839B by providing more information. For example, the camera 839C can be used to supply color information that is not discerned by cameras 839A and 839B. In some embodiments, one or more of the cameras 839A to 839D can include an optional IR cut filter configured to remove IR light from being received at the respective camera sensors.

The VR device 810 can include a housing 890 storing one or more components of the VR device 810 and/or additional components of the VR device 810. The housing 890 can be a modular electronic device configured to couple with the VR device 810 (or an AR device 800) and supplement and/or extend the capabilities of the VR device 810 (or an AR device 800). For example, the housing 890 can include additional sensors, cameras, power sources, processors (e.g., processor 848A-2), etc. to improve and/or increase the functionality of the VR device 810. Examples of the different components included in the housing 890 are described below in reference to FIG. 8C.

Alternatively or in addition, in some embodiments, the head-wearable device, such as the VR device 810 and/or the AR device 800), includes, or is communicatively coupled to, another external device (e.g., a paired device), such as an HIPD 9 (discussed below in reference to FIGS. 9A-9B) and/or an optional neckband. The optional neckband can couple to the head-wearable device via one or more connectors (e.g., wired or wireless connectors). The head-wearable device and the neckband can operate independently without any wired or wireless connection between them. In some embodiments, the components of the head-wearable device and the neckband are located on one or more additional peripheral devices paired with the head-wearable device, the neckband, or some combination thereof. Furthermore, the neckband is intended to represent any suitable type or form of paired device. Thus, the following discussion of neckband may also apply to various other paired devices, such as smart watches, smart phones, wrist bands, other wearable devices, hand-held controllers, tablet computers, or laptop computers.

In some situations, pairing external devices, such as an intermediary processing device (e.g., an HIPD device 900, an optional neckband, and/or wearable accessory device) with the head-wearable devices (e.g., an AR device 800 and/or VR device 810) enables the head-wearable devices to achieve a similar form factor of a pair of glasses while still providing sufficient battery and computation power for expanded capabilities. Some, or all, of the battery power, computational resources, and/or additional features of the head-wearable devices can be provided by a paired device or shared between a paired device and the head-wearable devices, thus reducing the weight, heat profile, and form factor of the head-wearable devices overall while allowing the head-wearable devices to retain its desired functionality. For example, the intermediary processing device (e.g., the HIPD 900) can allow components that would otherwise be included in a head-wearable device to be included in the intermediary processing device (and/or a wearable device or accessory device), thereby shifting a weight load from the user's head and neck to one or more other portions of the user's body. In some embodiments, the intermediary processing device has a larger surface area over which to diffuse and disperse heat to the ambient environment. Thus, the intermediary processing device can allow for greater battery and computation capacity than might otherwise have been possible on the head-wearable devices, standing alone. Because weight carried in the intermediary processing device can be less invasive to a user than weight carried in the head-wearable devices, a user may tolerate wearing a lighter eyewear device and carrying or wearing the paired device for greater lengths of time than the user would tolerate wearing a heavier eyewear device standing alone, thereby enabling an artificial-reality environment to be incorporated more fully into a user's day-to-day activities.

In some embodiments, the intermediary processing device is communicatively coupled with the head-wearable device and/or to other devices. The other devices may provide certain functions (e.g., tracking, localizing, depth mapping, processing, storage, etc.) to the head-wearable device. In some embodiments, the intermediary processing device includes a controller and a power source. In some embodiments, sensors of the intermediary processing device are configured to sense additional data that can be shared with the head-wearable devices in an electronic format (analog or digital).

The controller of the intermediary processing device processes information generated by the sensors on the intermediary processing device and/or the head-wearable devices. The intermediary processing device, like an HIPD 900, can process information generated by one or more sensors of its sensors and/or information provided by other communicatively coupled devices. For example, a head-wearable device can include an IMU, and the intermediary processing device (neckband and/or an HIPD 900) can compute all inertial and spatial calculations from the IMUs located on the head-wearable device. Additional examples of processing performed by a communicatively coupled device, such as the HIPD 900, are provided below in reference to FIGS. 9A and 9B.

Artificial-reality systems may include a variety of types of visual feedback mechanisms. For example, display devices in the AR devices 800 and/or the VR devices 810 may include one or more liquid-crystal displays (LCDs), light emitting diode (LED) displays, organic LED (OLED) displays, and/or any other suitable type of display screen. Artificial-reality systems may include a single display screen for both eyes or may provide a display screen for each eye, which may allow for additional flexibility for varifocal adjustments or for correcting a refractive error associated with the user's vision. Some artificial-reality systems also include optical subsystems having one or more lenses (e.g., conventional concave or convex lenses, Fresnel lenses, or adjustable liquid lenses) through which a user may view a display screen. In addition to or instead of using display screens, some artificial-reality systems include one or more projection systems. For example, display devices in the AR device 800 and/or the VR device 810 may include micro-LED projectors that project light (e.g., using a waveguide) into display devices, such as clear combiner lenses that allow ambient light to pass through. The display devices may refract the projected light toward a user's pupil and may enable a user to simultaneously view both artificial-reality content and the real world. Artificial-reality systems may also be configured with any other suitable type or form of image projection system. As noted, some AR systems may, instead of blending an artificial reality with actual reality, substantially replace one or more of a user's sensory perceptions of the real world with a virtual experience.

While the example head-wearable devices are respectively described herein as the AR device 800 and the VR device 810, either or both of the example head-wearable devices described herein can be configured to present fully-immersive VR scenes presented in substantially all of a user's field of view, additionally or alternatively to, subtler augmented-reality scenes that are presented within a portion, less than all, of the user's field of view.

In some embodiments, the AR device 800 and/or the VR device 810 can include haptic feedback systems. The haptic feedback systems may provide various types of cutaneous feedback, including vibration, force, traction, shear, texture, and/or temperature. The haptic feedback systems may also provide various types of kinesthetic feedback, such as motion and compliance. The haptic feedback can be implemented using motors, piezoelectric actuators, fluidic systems, and/or a variety of other types of feedback mechanisms. The haptic feedback systems may be implemented independently of other artificial-reality devices, within other artificial-reality devices, and/or in conjunction with other artificial-reality devices (e.g., wrist-wearable devices which may be incorporated into headwear, gloves, body suits, handheld controllers, environmental devices (e.g., chairs or floormats), and/or any other type of device or system, such as a wrist-wearable device 700, an HIPD 900, etc.), and/or other devices described herein.

FIG. 8C illustrates a computing system 820 and an optional housing 890, each of which show components that can be included in a head-wearable device (e.g., the AR device 800 and/or the VR device 810). In some embodiments, more or less components can be included in the optional housing 890 depending on practical restraints of the respective head-wearable device being described. Additionally or alternatively, the optional housing 890 can include additional components to expand and/or augment the functionality of a head-wearable device.

In some embodiments, the computing system 820 and/or the optional housing 890 can include one or more peripheral interfaces 822A and822B, one or more power systems 842A and 842B (including charger input 843, PMIC 844, and battery 845), one or more controllers 846A 846B (including one or more haptic controllers 847), one or more processors 848A and 848B (as defined above, including any of the examples provided), and memory 850A and 850B, which can all be in electronic communication with each other. For example, the one or more processors 848A and/or 848B can be configured to execute instructions stored in the memory 850A and/or 850B, which can cause a controller of the one or more controllers 846A and/or 846B to cause operations to be performed at one or more peripheral devices of the peripherals interfaces 822A and/or 822B. In some embodiments, each operation described can occur based on electrical power provided by the power system 842A and/or 842B.

In some embodiments, the peripherals interface 822A can include one or more devices configured to be part of the computing system 820, many of which have been defined above and/or described with respect to wrist-wearable devices shown in FIGS. 7A and 7B. For example, the peripherals interface can include one or more sensors 823A. Some example sensors include: one or more coupling sensors 824, one or more acoustic sensors 825, one or more imaging sensors 826, one or more EMG sensors 827, one or more capacitive sensors 828, and/or one or more IMUs 829. In some embodiments, the sensors 823A further include depth sensors 867, light sensors 868, temperature sensors 869, and/or any other types of sensors defined above or described with respect to any other embodiments discussed herein.

In some embodiments, the peripherals interface can include one or more additional peripheral devices, including one or more NFC devices 830, one or more GPS devices 831, one or more LTE devices 832, one or more WiFi and/or Bluetooth devices 833, one or more buttons 834 (e.g., including buttons that are slidable or otherwise adjustable), one or more displays 835A, one or more speakers 836A, one or more microphones 837A, one or more cameras 838A (e.g., including the a first camera 839-1 through nth camera 839-n, which are analogous to the left camera 839A and/or the right camera 839B), one or more haptic devices 840; and/or any other types of peripheral devices defined above or described with respect to any other embodiments discussed herein.

The head-wearable devices can include a variety of types of visual feedback mechanisms (e.g., presentation devices). For example, display devices in the AR device 800 and/or the VR device 810 can include one or more liquid-crystal displays (LCDs), light emitting diode (LED) displays, organic LED (OLED) displays, micro-LEDs, and/or any other suitable types of display screens. The head-wearable devices can include a single display screen (e.g., configured to be seen by both eyes), and/or can provide separate display screens for each eye, which can allow for additional flexibility for varifocal adjustments and/or for correcting a refractive error associated with the user's vision. Some embodiments of the head-wearable devices also include optical subsystems having one or more lenses (e.g., conventional concave or convex lenses, Fresnel lenses, or adjustable liquid lenses) through which a user can view a display screen. For example, respective displays 835A can be coupled to each of the lenses 806-1 and 806-2 of the AR device 800. The displays 835A coupled to each of the lenses 806-1 and 806-2 can act together or independently to present an image or series of images to a user. In some embodiments, the AR device 800 and/or the VR device 810 includes a single display 835A (e.g., a near-eye display) or more than two displays 835A.

In some embodiments, a first set of one or more displays 835A can be used to present an augmented-reality environment, and a second set of one or more display devices 835A can be used to present a virtual-reality environment. In some embodiments, one or more waveguides are used in conjunction with presenting artificial-reality content to the user of the AR device 800 and/or the VR device 810 (e.g., as a means of delivering light from a display projector assembly and/or one or more displays 835A to the user's eyes). In some embodiments, one or more waveguides are fully or partially integrated into the AR device 800 and/or the VR device 810. Additionally, or alternatively to display screens, some artificial-reality systems include one or more projection systems. For example, display devices in the AR device 800 and/or the VR device 810 can include micro-LED projectors that project light (e.g., using a waveguide) into display devices, such as clear combiner lenses that allow ambient light to pass through. The display devices can refract the projected light toward a user's pupil and can enable a user to simultaneously view both artificial-reality content and the real world. The head-wearable devices can also be configured with any other suitable type or form of image projection system. In some embodiments, one or more waveguides are provided additionally or alternatively to the one or more display(s) 835A.

In some embodiments of the head-wearable devices, ambient light and/or a real-world live view (e.g., a live feed of the surrounding environment that a user would normally see) can be passed through a display element of a respective head-wearable device presenting aspects of the AR system. In some embodiments, ambient light and/or the real-world live view can be passed through a portion less than all, of an AR environment presented within a user's field of view (e.g., a portion of the AR environment co-located with a physical object in the user's real-world environment that is within a designated boundary (e.g., a guardian boundary) configured to be used by the user while they are interacting with the AR environment). For example, a visual user interface element (e.g., a notification user interface element) can be presented at the head-wearable devices, and an amount of ambient light and/or the real-world live view (e.g., 15-50% of the ambient light and/or the real-world live view) can be passed through the user interface element, such that the user can distinguish at least a portion of the physical environment over which the user interface element is being displayed.

The head-wearable devices can include one or more external displays 835A for presenting information to users. For example, an external display 835A can be used to show a current battery level, network activity (e.g., connected, disconnected, etc.), current activity (e.g., playing a game, in a call, in a meeting, watching a movie, etc.), and/or other relevant information. In some embodiments, the external displays 835A can be used to communicate with others. For example, a user of the head-wearable device can cause the external displays 835A to present a do not disturb notification. The external displays 835A can also be used by the user to share any information captured by the one or more components of the peripherals interface 822A and/or generated by head-wearable device (e.g., during operation and/or performance of one or more applications).

The memory 850A can include instructions and/or data executable by one or more processors 848A (and/or processors 848B of the housing 890) and/or a memory controller of the one or more controllers 846A (and/or controller 846B of the housing 890). The memory 850A can include one or more operating systems 851; one or more applications 852; one or more communication interface modules 853A; one or more graphics modules 854A; one or more AR processing modules 855A; thermal management module 856A for managing byproduct heat in the head-wearable device; and/or any other types of modules or components defined above or described with respect to any other embodiments discussed herein.

The data 860 stored in memory 850A can be used in conjunction with one or more of the applications and/or programs discussed above. The data 860 can include profile data 861; sensor data 862; media content data 863; AR application data 864; temperature data 865A for managing the thermal design power (TDP) of the head-wearable device; and/or any other types of data defined above or described with respect to any other embodiments discussed herein.

In some embodiments, the controller 846A of the head-wearable devices processes information generated by the sensors 823A on the head-wearable devices and/or another component of the head-wearable devices and/or communicatively coupled with the head-wearable devices (e.g., components of the housing 890, such as components of peripherals interface 822B). For example, the controller 846A can process information from the acoustic sensors 825 and/or image sensors 826. For each detected sound, the controller 846A can perform a direction of arrival (DOA) estimation to estimate a direction from which the detected sound arrived at a head-wearable device. As one or more of the acoustic sensors 825 detects sounds, the controller 846A can populate an audio data set with the information (e.g., represented by sensor data 862).

In some embodiments, a physical electronic connector can convey information between the head-wearable devices and another electronic device, and/or between one or more processors 848A of the head-wearable devices and the controller 846A. The information can be in the form of optical data, electrical data, wireless data, or any other transmittable data form. Moving the processing of information generated by the head-wearable devices to an intermediary processing device can reduce weight and heat in the eyewear device, making it more comfortable and safer for a user. In some embodiments, an optional accessory device (e.g., an electronic neckband or an HIPD 900) is coupled to the head-wearable devices via one or more connectors. The connectors can be wired or wireless connectors and can include electrical and/or non-electrical (e.g., structural) components. In some embodiments, the head-wearable devices and the accessory device can operate independently without any wired or wireless connection between them.

The head-wearable devices can include various types of computer vision components and subsystems. For example, the AR device 800 and/or the VR device 810 can include one or more optical sensors such as two-dimensional (2D) or three-dimensional (3D) cameras, time-of-flight depth sensors, single-beam or sweeping laser rangefinders, 3D LiDAR sensors, and/or any other suitable type or form of optical sensor. A head-wearable device can process data from one or more of these sensors to identify a location of a user and/or aspects of the use's real-world physical surroundings, including the locations of real-world objects within the real-world physical surroundings. In some embodiments, the methods described herein are used to map the real world, to provide a user with context about real-world surroundings, and/or to generate interactable virtual objects (which can be replicas or digital twins of real-world objects that can be interacted with in AR environment), among a variety of other functions. For example, FIGS. 8B-1 and 8B-2 show the VR device 810 having cameras 839A-839D, which can be used to provide depth information for creating a voxel field and a two-dimensional mesh to provide object information to the user to avoid collisions.

The optional housing 890 can include analogous components to those describe above with respect to the computing system 820. For example, the optional housing 890 can include a respective peripherals interface 822B including more or less components to those described above with respect to the peripherals interface 822A. As described above, the components of the optional housing 890 can be used augment and/or expand on the functionality of the head-wearable devices. For example, the optional housing 890 can include respective sensors 823B, speakers 836B, displays 835B, microphones 837B, cameras 838B, and/or other components to capture and/or present data. Similarly, the optional housing 890 can include one or more processors 848B, controllers 846B, and/or memory 850B (including respective communication interface modules 853B; one or more graphics modules 854B; one or more AR processing modules 855B, etc.) that can be used individually and/or in conjunction with the components of the computing system 820.

The techniques described above in FIGS. 8A-8C can be used with different head-wearable devices. In some embodiments, the head-wearable devices (e.g., the AR device 800 and/or the VR device 810) can be used in conjunction with one or more wearable device such as a wrist-wearable device 700 (or components thereof). Having thus described example the head-wearable devices, attention will now be turned to example handheld intermediary processing devices, such as HIPD 900.

### Example Handheld Intermediary Processing Devices

FIGS. 9A and 9B illustrate an example handheld intermediary processing device (HIPD) 900, in accordance with some embodiments. The HIPD 900 can perform various functions and/or operations associated with navigating through user interfaces and selectively opening applications.

FIG. 9A shows a top view 905 and a side view 925 of the HIPD 900. The HIPD 900 is configured to communicatively couple with one or more wearable devices (or other electronic devices) associated with a user. For example, the HIPD 900 is configured to communicatively couple with a user's wrist-wearable device 700 (or components thereof, such as the watch body 720 and the wearable band 710), AR device 800, and/or VR device 810. The HIPD 900 can be configured to be held by a user (e.g., as a handheld controller), carried on the user's person (e.g., in their pocket, in their bag, etc.), placed in proximity of the user (e.g., placed on their desk while seated at their desk, on a charging dock, etc.), and/or placed at or within a predetermined distance from a wearable device or other electronic device (e.g., where, in some embodiments, the predetermined distance is the maximum distance (e.g., 10 meters) at which the HIPD 900 can successfully be communicatively coupled with an electronic device, such as a wearable device).

The HIPD 900 can perform various functions independently and/or in conjunction with one or more wearable devices (e.g., wrist-wearable device 700, AR device 800, VR device 810, etc.). The HIPD 900 is configured to increase and/or improve the functionality of communicatively coupled devices, such as the wearable devices. The HIPD 900 is configured to perform one or more functions or operations associated with interacting with user interfaces and applications of communicatively coupled devices, interacting with an AR environment, interacting with VR environment, and/or operating as a human-machine interface controller. Additionally, as will be described in more detail below, functionality and/or operations of the HIPD 900 can include, without limitation, task offloading and/or handoffs; thermals offloading and/or handoffs; 6 degrees of freedom (6DoF) raycasting and/or gaming (e.g., using imaging devices or cameras 914A and 914B, which can be used for simultaneous localization and mapping (SLAM) and/or with other image processing techniques); portable charging; messaging; image capturing via one or more imaging devices or cameras (e.g., cameras 922A and 922B); sensing user input (e.g., sensing a touch on a multi-touch input surface 902); wireless communications and/or interlining (e.g., cellular, near field, Wi-Fi, personal area network, etc.); location determination; financial transactions; providing haptic feedback; alarms; notifications; biometric authentication; health monitoring; sleep monitoring; etc. The above-example functions can be executed independently in the HIPD 900 and/or in communication between the HIPD 900 and another wearable device described herein. In some embodiments, functions can be executed on the HIPD 900 in conjunction with an AR environment. As the skilled artisan will appreciate upon reading the descriptions provided herein, the novel the HIPD 900 described herein can be used with any type of suitable AR environment.

While the HIPD 900 is communicatively coupled with a wearable device and/or other electronic device, the HIPD 900 is configured to perform one or more operations initiated at the wearable device and/or the other electronic device. In particular, one or more operations of the wearable device and/or the other electronic device can be offloaded to the HIPD 900 to be performed. The HIPD 900 performs the one or more operations of the wearable device and/or the other electronic device and provides to data corresponded to the completed operations to the wearable device and/or the other electronic device. For example, a user can initiate a video stream using AR device 800 and back-end tasks associated with performing the video stream (e.g., video rendering) can be offloaded to the HIPD 900, which the HIPD 900 performs and provides corresponding data to the AR device 800 to perform remaining front-end tasks associated with the video stream (e.g., presenting the rendered video data via a display of the AR device 800). In this way, the HIPD 900, which has more computational resources and greater thermal headroom than a wearable device, can perform computationally intensive tasks for the wearable device improving performance of an operation performed by the wearable device.

The HIPD 900 includes a multi-touch input surface 902 on a first side (e.g., a front surface) that is configured to detect one or more user inputs. In particular, the multi-touch input surface 902 can detect single tap inputs, multi-tap inputs, swipe gestures and/or inputs, force-based and/or pressure-based touch inputs, held taps, and the like. The multi-touch input surface 902 is configured to detect capacitive touch inputs and/or force (and/or pressure) touch inputs. The multi-touch input surface 902 includes a first touch-input surface 904 defined by a surface depression, and a second touch-input surface 906 defined by a substantially planar portion. The first touch-input surface 904 can be disposed adjacent to the second touch-input surface 906. In some embodiments, the first touch-input surface 904 and the second touch-input surface 906 can be different dimensions, shapes, and/or cover different portions of the multi-touch input surface 902. For example, the first touch-input surface 904 can be substantially circular and the second touch-input surface 906 is substantially rectangular. In some embodiments, the surface depression of the multi-touch input surface 902 is configured to guide user handling of the HIPD 900. In particular, the surface depression is configured such that the user holds the HIPD 900 upright when held in a single hand (e.g., such that the using imaging devices or cameras 914A and 914B are pointed toward a ceiling or the sky). Additionally, the surface depression is configured such that the user's thumb rests within the first touch-input surface 904.

In some embodiments, the different touch-input surfaces include a plurality of touch-input zones. For example, the second touch-input surface 906 includes at least a first touch-input zone 908 within a second touch-input zone 906 and a third touch-input zone 910 within the first touch-input zone 908. In some embodiments, one or more of the touch-input zones are optional and/or user defined (e.g., a user can specific a touch-input zone based on their preferences). In some embodiments, each touch-input surface and/or touch-input zone is associated with a predetermined set of commands. For example, a user input detected within the first touch-input zone 908 causes the HIPD 900 to perform a first command and a user input detected within the second touch-input zone 906 causes the HIPD 900 to perform a second command, distinct from the first. In some embodiments, different touch-input surfaces and/or touch-input zones are configured to detect one or more types of user inputs. The different touch-input surfaces and/or touch-input zones can be configured to detect the same or distinct types of user inputs. For example, the first touch-input zone 908 can be configured to detect force touch inputs (e.g., a magnitude at which the user presses down) and capacitive touch inputs, and the second touch-input zone 906 can be configured to detect capacitive touch inputs.

The HIPD 900 includes one or more sensors 951 for sensing data used in the performance of one or more operations and/or functions. For example, the HIPD 900 can include an IMU that is used in conjunction with cameras 914 for 3-dimensional object manipulation (e.g., enlarging, moving, destroying, etc. an object) in an AR or VR environment. Non-limiting examples of the sensors 951 included in the HIPD 900 include a light sensor, a magnetometer, a depth sensor, a pressure sensor, and a force sensor. Additional examples of the sensors 951 are provided below in reference to FIG. 9B.

The HIPD 900 can include one or more light indicators 912 to provide one or more notifications to the user. In some embodiments, the light indicators are LEDs or other types of illumination devices. The light indicators 912 can operate as a privacy light to notify the user and/or others near the user that an imaging device and/or microphone are active. In some embodiments, a light indicator is positioned adjacent to one or more touch-input surfaces. For example, a light indicator can be positioned around the first touch-input surface 904. The light indicators can be illuminated in different colors and/or patterns to provide the user with one or more notifications and/or information about the device. For example, a light indicator positioned around the first touch-input surface 904 can flash when the user receives a notification (e.g., a message), change red when the HIPD 900 is out of power, operate as a progress bar (e.g., a light ring that is closed when a task is completed (e.g., 0% to 100%)), operates as a volume indicator, etc.).

In some embodiments, the HIPD 900 includes one or more additional sensors on another surface. For example, as shown FIG. 9A, HIPD 900 includes a set of one or more sensors (e.g., sensor set 920) on an edge of the HIPD 900. The sensor set 920, when positioned on an edge of the of the HIPD 900, can be pre positioned at a predetermined tilt angle (e.g., 26 degrees), which allows the sensor set 920 to be angled toward the user when placed on a desk or other flat surface. Alternatively, in some embodiments, the sensor set 920 is positioned on a surface opposite the multi-touch input surface 902 (e.g., a back surface). The one or more sensors of the sensor set 920 are discussed in detail below.

The side view 925 of the of the HIPD 900 shows the sensor set 920 and camera 914B. The sensor set 920 includes one or more cameras 922A and 922B, a depth projector 924, an ambient light sensor 928, and a depth receiver 930. In some embodiments, the sensor set 920 includes a light indicator 926. The light indicator 926 can operate as a privacy indicator to let the user and/or those around them know that a camera and/or microphone is active. The sensor set 920 is configured to capture a user's facial expression such that the user can puppet a custom avatar (e.g., showing emotions, such as smiles, laughter, etc., on the avatar or a digital representation of the user). The sensor set 920 can be configured as a side stereo RGB system, a rear indirect Time-of-Flight (iToF) system, or a rear stereo RGB system. As the skilled artisan will appreciate upon reading the descriptions provided herein, the novel HIPD 900 described herein can use different sensor set 920 configurations and/or sensor set 920 placement.

In some embodiments, the HIPD 900 includes one or more haptic devices 971 (FIG. 9B; e.g., a vibratory haptic actuator) that are configured to provide haptic feedback (e.g., kinesthetic sensation). The sensors 951, and/or the haptic devices 971 can be configured to operate in conjunction with multiple applications and/or communicatively coupled devices including, without limitation, a wearable devices, health monitoring applications, social media applications, game applications, and artificial reality applications (e.g., the applications associated with artificial reality).

The HIPD 900 is configured to operate without a display. However, in optional embodiments, the HIPD 900 can include a display 968 (FIG. 9B). The HIPD 900 can also income one or more optional peripheral buttons 967 (FIG. 9B). For example, the peripheral buttons 967 can be used to turn on or turn off the HIPD 900. Further, the HIPD 900 housing can be formed of polymers and/or elastomer elastomers. The HIPD 900 can be configured to have a non-slip surface to allow the HIPD 900 to be placed on a surface without requiring a user to watch over the HIPD 900. In other words, the HIPD 900 is designed such that it would not easily slide off a surfaces. In some embodiments, the HIPD 900 include one or magnets to couple the HIPD 900 to another surface. This allows the user to mount the HIPD 900 to different surfaces and provide the user with greater flexibility in use of the HIPD 900.

As described above, the HIPD 900 can distribute and/or provide instructions for performing the one or more tasks at the HIPD 900 and/or a communicatively coupled device. For example, the HIPD 900 can identify one or more back-end tasks to be performed by the HIPD 900 and one or more front-end tasks to be performed by a communicatively coupled device. While the HIPD 900 is configured to offload and/or handoff tasks of a communicatively coupled device, the HIPD 900 can perform both back-end and front-end tasks (e.g., via one or more processors, such as CPU 977; FIG. 9B). The HIPD 900 can, without limitation, can be used to perform augmenting calling (e.g., receiving and/or sending 3D or 2.5D live volumetric calls, live digital human representation calls, and/or avatar calls), discreet messaging, 6DoF portrait/landscape gaming, AR/VR object manipulation, AR/VR content display (e.g., presenting content via a virtual display), and/or other AR/VR interactions. The HIPD 900 can perform the above operations alone or in conjunction with a wearable device (or other communicatively coupled electronic device).

FIG. 9B shows block diagrams of a computing system 940 of the HIPD 900, in accordance with some embodiments. The HIPD 900, described in detail above, can include one or more components shown in HIPD computing system 940. The HIPD 900 will be understood to include the components shown and described below for the HIPD computing system 940. In some embodiments, all, or a substantial portion of the components of the HIPD computing system 940 are included in a single integrated circuit. Alternatively, in some embodiments, components of the HIPD computing system 940 are included in a plurality of integrated circuits that are communicatively coupled.

The HIPD computing system 940 can include a processor (e.g., a CPU 977, a GPU, and/or a CPU with integrated graphics), a controller 975, a peripherals interface 950 that includes one or more sensors 951 and other peripheral devices, a power source (e.g., a power system 995), and memory (e.g., a memory 978) that includes an operating system (e.g., an operating system 979), data (e.g., data 988), one or more applications (e.g., applications 980), and one or more modules (e.g., a communications interface module 981, a graphics module 982, a task and processing management module 983, an interoperability module 984, an AR processing module 985, a data management module 986, etc.). The HIPD computing system 940 further includes a power system 995 that includes a charger input and output 996, a PMIC 997, and a battery 998, all of which are defined above.

In some embodiments, the peripherals interface 950 can include one or more sensors 951. The sensors 951 can include analogous sensors to those described above in reference to FIG. 7B. For example, the sensors 951 can include imaging sensors 954, (optional) EMG sensors 956, IMUs 958, and capacitive sensors 960. In some embodiments, the sensors 951 can include one or more pressure sensor 952 for sensing pressure data, an altimeter 953 for sensing an altitude of the HIPD 900, a magnetometer 955 for sensing a magnetic field, a depth sensor 957 (or a time-of flight sensor) for determining a difference between the camera and the subject of an image, a position sensor 959 (e.g., a flexible position sensor) for sensing a relative displacement or position change of a portion of the HIPD 900, a force sensor 961 for sensing a force applied to a portion of the HIPD 900, and a light sensor 962 (e.g., an ambient light sensor) for detecting an amount of lighting. The sensors 951 can include one or more sensors not shown in FIG. 9B.

Analogous to the peripherals described above in reference to FIGS. 7B, the peripherals interface 950 can also include an NFC component 963, a GPS component 964, an LTE component 965, a Wi-Fi and/or Bluetooth communication component 966, a speaker 969, a haptic device 971, and a microphone 973. As described above in reference to FIG. 9A, the HIPD 900 can optionally include a display 968 and/or one or more buttons 967. The peripherals interface 950 can further include one or more cameras 970, touch surfaces 972, and/or one or more light emitters 974. The multi-touch input surface 902 described above in reference to FIG. 9A is an example of touch surface 972. The light emitters 974 can be one or more LEDs, lasers, etc. and can be used to project or present information to a user. For example, the light emitters 974 can include light indicators 912 and 926 described above in reference to FIG. 9A. The cameras 970 (e.g., cameras 914A, 914B, and 922 described above in FIG. 9A) can include one or more wide angle cameras, fish-eye cameras, spherical cameras, compound eye cameras (e.g., stereo and multi cameras), depth cameras, RGB cameras, ToF cameras, RGB-D cameras (depth and ToF cameras), and/or other available cameras. Cameras 970 can be used for SLAM; 6 DoF ray casting, gaming, object manipulation, and/or other rendering; facial recognition and facial expression recognition, etc.

Similar to the watch body computing system 760 and the watch band computing system 730 described above in reference to FIG. 7B, the HIPD computing system 940 can include one or more haptic controllers 976 and associated componentry (e.g., haptic devices 971) for providing haptic events at the HIPD 900.

Memory 978 can include high-speed random-access memory and/or non-volatile memory, such as one or more magnetic disk storage devices, flash memory devices, or other non-volatile solid-state memory devices. Access to the memory 978 by other components of the HIPD 900, such as the one or more processors and the peripherals interface 950, can be controlled by a memory controller of the controllers 975.

In some embodiments, software components stored in the memory 978 include one or more operating systems 979, one or more applications 980, one or more communication interface modules 981, one or more graphics modules 982, one or more data management modules 985, which are analogous to the software components described above in reference to FIG. 7B.

In some embodiments, software components stored in the memory 978 include a task and processing management module 983 for identifying one or more front-end and back-end tasks associated with an operation performed by the user, performing one or more front-end and/or back-end tasks, and/or providing instructions to one or more communicatively coupled devices that cause performance of the one or more front-end and/or back-end tasks. In some embodiments, the task and processing management module 983 uses data 988 (e.g., device data 990) to distribute the one or more front-end and/or back-end tasks based on communicatively coupled devices' computing resources, available power, thermal headroom, ongoing operations, and/or other factors. For example, the task and processing management module 983 can cause the performance of one or more back-end tasks (of an operation performed at communicatively coupled AR device 800) at the HIPD 900 in accordance with a determination that the operation is utilizing a predetermined amount (e.g., at least 70%) of computing resources available at the AR device 800.

In some embodiments, software components stored in the memory 978 include an interoperability module 984 for exchanging and utilizing information received and/or provided to distinct communicatively coupled devices. The interoperability module 984 allows for different systems, devices, and/or applications to connect and communicate in a coordinated way without user input. In some embodiments, software components stored in the memory 978 include an AR module 985 that is configured to process signals based at least on sensor data for use in an AR and/or VR environment. For example, the AR processing module 985 can be used for 3D object manipulation, gesture recognition, facial and facial expression, recognition, etc.

The memory 978 can also include data 987, including structured data. In some embodiments, the data 987 can include profile data 989, device data 989 (including device data of one or more devices communicatively coupled with the HIPD 900, such as device type, hardware, software, configurations, etc.), sensor data 991, media content data 992, and application data 993.

It should be appreciated that the HIPD computing system 940 is an example of a computing system within the HIPD 900, and that the HIPD 900 can have more or fewer components than shown in the HIPD computing system 940, combine two or more components, and/or have a different configuration and/or arrangement of the components. The various components shown in HIPD computing system 940 are implemented in hardware, software, firmware, or a combination thereof, including one or more signal processing and/or application-specific integrated circuits.

The techniques described above in FIG. 9A-9B can be used with any device used as a human-machine interface controller. In some embodiments, an HIPD 900 can be used in conjunction with one or more wearable device such as a head-wearable device (e.g., AR device 800 and VR device 810) and/or a wrist-wearable device 700 (or components thereof).

Any data collection performed by the devices described herein and/or any devices configured to perform or cause the performance of the different embodiments described above in reference to any of the Figures, hereinafter the “devices,” is done with user consent and in a manner that is consistent with all applicable privacy laws. Users are given options to allow the devices to collect data, as well as the option to limit or deny collection of data by the devices. A user is able to opt-in or opt-out of any data collection at any time. Further, users are given the option to request the removal of any collected data.

It will be understood that, although the terms “first,” “second,” etc. may be used herein to describe various elements, these elements should not be limited by these terms. These terms are only used to distinguish one element from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” can be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” can be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

What is claimed is:

1. A head worn device, comprising:
a lens frame configured to receive at least two lenses;
a first temple arm coupled via a hinge to the lens frame;
one or more electrical components located within the first temple arm, wherein the one or more electrical components emit heat when operating;
a heat-transfer component configured to transfer the heat from the one or more electrical components via the hinge to a first lens of the lens frame, wherein transferring the heat from the one or more electrical components to the first lens of the lens frame is configured to maintain the one or more electrical components operating within their respective thermal design power (TDP).

2. The head worn device of claim 1, wherein the heat-transfer component includes one or more of: (i) an overmolded carbon tape that is affixed to the first temple arm, and is further configured to bend with the hinge, (ii) a flexible heat pipe that is configured to bend with the hinge, and/or carbon tape that is configured to bend with the hinge.

3. The head worn device of claim 1, comprising:
a second temple arm coupled via another hinge to the lens frame opposite to where the first temple arm is connected to the lens frame;
one or more additional electrical components located within the second temple arm, wherein the one or more additional electrical components emit additional heat when operating;
another heat transfer component configured to transfer the additional heat from the one or more additional electrical components to a second lens of the lens frame, wherein transferring the additional heat from the one or more additional electrical components to the second lens of the lens frame is configured to cause lengthening of a time during which the one or more additional electrical components can operate at their respective TDP.

4. The head worn device of claim 1, wherein one or both of the lens frame or first temple arm are constructed of one or more of: magnesium, polycarbonate, or a metal matrix composite.

5. The head worn device of claim 1, wherein one of the electrical components is one of: a camera, a processor, a display projector component, a graphics processor, or a sensor.

6. The head worn device of claim 1, wherein the one or more electrical components can actively adjust their respective TDP based on temperature measured at one or more locations on the first temple arm.

7. The head worn device of claim 6, wherein the temperature measured at the one or more locations correspond to temperature hot spots on the first temple arm, wherein a temperature hot spot is a location where the maximum temperature limit is reached first.

8. The head worn device of claim 1, wherein the one or more electrical components can actively adjust their feature set in stages based on temperature measured at one or more locations on the first temple arm.

9. The head worn device of claim 1, wherein the one or more electrical components actively adjust their respective TDP in accordance with a determination that the head worn device is either located indoors or outdoors.

10. The head worn device of claim 1, including:
one or more additional electrical components located within the lens frame at a first location, wherein the one or more additional electrical components emit heat when operating; and
another heat-transfer component configured to transfer the heat from the one or more additional electrical components to a second location on the lens frame, wherein:
the second location on the lens frame is a location that is configured to be in minimal contact with skin of a user, and
transferring the additional heat from the one or more additional electrical components to the second location on the lens frame is configured to cause lengthening of a time duration during which the one or more additional electrical components can operate at their respective TDP.

11. The head worn device of claim 10, wherein:
the heat-transfer component is a heat pipe,
the first location is a location that corresponds with a nose bridge of a user, and
the second location is a location that corresponds with outer edge of the lens frame that is configured to not be in contact with a face of the user.

12. The head worn device of claim 1, including:
one or more additional electrical components located within the lens frame, wherein the one or more additional electrical components emit heat when operating; and
another heat-transfer component configured to transfer the heat from the one or more additional electrical components to a location on the temple arm, wherein:
the location on the temple arm is a location that is configured to be in minimal contact with skin of a user, and
transferring the additional heat from the one or more additional electrical components to the temple arm is configured to cause lengthening of a time duration during which the one or more additional electrical components can operate at their respective TDP.

13. A lens, comprising:
a feature for mounting the lens in a lens frame of a head worn device;
a heat-transfer component configured to transfer heat from one or more electrical components located within a first temple arm that is hingeably coupled to the lens frame, wherein:
the one or more electrical components emit heat when operating, and
transferring the heat from the one or more electrical components to the lens in the lens frame is configured to cause lengthening of a time duration during which the one or more electrical components can operate at their respective TDP.

14. The lens of claim 13, wherein the heat-transfer component includes one or more of: (i) an overmolded carbon tape that is affixed to the first temple arm, and is further configured to bend with the hinge, (ii) a flexible heat pipe that is configured to bend with the hinge, and/or carbon tape that is configured to bend with the hinge.

15. The lens of claim 13, wherein one of the electrical components is one of: a camera, a processor, a display projector component, a graphics processor, or a sensor.

16. The lens of claim 13, wherein the one or more electrical components can actively adjust their respective TDP based on temperature measured at one or more locations on the first temple arm.

17. A temple arm, comprising:
a heat-transfer component configured to transfer the heat from one or more electrical components via a hinge to a first lens of a lens frame, wherein:
the lens frame is configured to receive at least two lenses,
the one or more electrical components emit heat when operating, and
transferring the heat from the one or more electrical components to the first lens of the lens frame is configured to maintain the one or more electrical components operating within their respective thermal design power (TDP).

18. The temple arm of claim 17, wherein the heat-transfer component includes one or more of: (i) an overmolded carbon tape that is affixed to the temple arm, and is further configured to bend with the hinge, (ii) a flexible heat pipe that is configured to bend with the hinge, and/or carbon tape that is configured to bend with the hinge.

19. The temple arm of claim 17, wherein one of the electrical components is one of: a camera, a processor, a display projector component, a graphics processor, or a sensor.

20. The temple arm of claim 17, wherein the one or more electrical components can actively adjust their respective TDP based on temperature measured at one or more locations on the temple arm.
